(19) United States
(12) Patent Application Publication
(10) Pub. No.: US 2025/0107003 A1
(43) Pub. Date: Mar. 27, 2025

(54) METHODS AND APPARATUS TO MANAGE NOISE FOR TIMING CIRCUITRY

(71) Applicant: Intel Corporation, Santa Clara, CA (US)

(72) Inventors: Chin Mian Choong, Georgetown (MY); Jiun Hann Sir, Gelugor (MY); Poh Boon Khoo, Perai (MY); Wei Jern Tan, Georgetown (MY); Boon Ping Koh, Seberang Jaya (MY)

(21) Appl. No.: 18/475,920

(22) Filed: Sep. 27, 2023

(51) Int. Cl. H05K 1/18; H01L 23/498; H01L 25/18; H05K 1/14; H05K 3/40; H05K 3/46; H10B 80/00

(52) U.S. Cl. CPC H05K 1/181; H01L 23/49811; H05K 1/141; H05K 3/4007; H05K 3/4608; H05K 3/4647; H01L 25/18; H05K 2201/041; H05K 2201/10378; H05K 2201/10515; H05K 2201/10522; H05K 2201/1053; H05K 2203/1327; H10B 80/00

(57) ABSTRACT

Systems, apparatus, articles of manufacture, and methods are disclosed comprising: an integrated circuit package including a package substrate, the package substrate including a first contact and a second contact, the first contact to be electrically coupled to a printed circuit board (PCB); and a timing package distinct from the integrated circuit package, the timing package including a third contact, the third contact to be electrically coupled to the second contact independent of the PCB.

### FIELD OF THE DISCLOSURE

This disclosure relates generally to timing circuitry and, more particularly, to methods and apparatus to manage noise for timing circuitry.

### BACKGROUND

Advancements in electronics design and manufacturing have allowed designers to create increasingly complex devices. Such devices are capable of an increasingly wide range of operations. As electronics continue to advance, designers are incentivized to design devices that utilize a wide range of voltages to perform an increasing variety of operations using a single printed circuit board (PCB).

### BRIEF DESCRIPTION OF THE DRAWINGS

FIG. 1 is a block diagram of an example integrated circuit package assembly including an example PCB and an example timing package.

FIG. 2 is a block diagram of an example cross-sectional view of an example implementation of the example integrated circuit package assembly of FIG. 1 taken along line 2-2 of FIG. 1.

FIG. 3 is a schematic diagram of an example top view of the example timing package of FIG. 2.

FIG. 4 is a schematic diagram of an example top view of the first conductive layer in the example timing package of FIGS. 2 and 3.

FIG. 5 is a schematic diagram of an example top view of the second conductive layer in the example timing package of FIGS. 2 and 3.

FIGS. 6-14 are schematic diagrams representative of different stages of fabrication of the example timing package of FIGS. 2-5.

FIG. 15 is a flowchart representative of the example operations to manufacture the example timing package of FIGS. 2-5 in accordance with the stages of fabrication represented in FIGS. 6-14.

FIG. 16 is a block diagram of a first example cross-sectional view of another example implementation of the example timing package of FIG. 1 similar to the timing package shown in FIG. 2 but further including an example additional copper layer and an example solder resist layer.

FIG. 17 is a block diagram of a second example cross-sectional view of the example timing package of FIG. 16 taken along line 17-17 of FIG. 1.

FIG. 18 is a schematic diagram of an example top view of the example timing package of FIGS. 16 and 17.

FIG. 19 is a schematic diagram of an example top view of the solder resist layer of the example timing package of FIGS. 16-18.

FIG. 20 is a schematic diagram of an example top view of the additional copper layer of example the timing package of FIGS. 16-19.

FIG. 21 is a flowchart representative of the example operations to manufacture the example timing package of FIG. 16-20.

FIG. 22 is a block diagram of another example integrated circuit package assembly including an example PCB, an example timing package, and an example integrated circuit package.

FIG. 23 is a block diagram of an example cross-sectional view of an example implementation of the example package of FIG. 22 taken along lines 23-23 of FIG. 22.

FIG. 24 is a schematic diagram of an example top view of the example timing package of FIG. 23.

FIG. 25 is a schematic diagram of an example top view of the first conductive layer of the example timing package of FIGS. 22 and 23.

FIG. 26 is a schematic diagram of an example top view of the second conductive layer of the example timing package of FIGS. 22-25.

FIG. 27 is a block diagram of a first example cross-sectional view of another example implementation of the timing package of FIG. 22 similar to the timing package shown in FIG. 23 but further including an example additional copper layer and an example solder resist layer.

FIG. 28 is a block diagram of a second example cross-sectional view of the example timing package of FIG. 27 taken along line 28-28 of FIG. 22.

FIG. 29 is a cross-sectional side view of an IC package assembly that may include an example timing package constructed in accordance with teachings disclosed herein.

FIG. 30 is a block diagram of an example electrical device that may include a timing package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Advancements in electronics design and manufacturing have allowed designers to create increasingly complex devices. Such devices are capable of an increasingly wide range of operations. As electronics continue to advance, designers are incentivized to design devices that utilize a wide range of voltages to perform an increasing variety of operations using a single printed circuit board (PCB). Some devices split circuitry between a PCB and one or more integrated circuit (IC) packages.

The PCB supports circuitry that is configured to perform operations of the device. Also, the PCB supports operations of IC packages mounted to the PCB by routing signals to and/or from the IC packages. The PCB includes electrical traces that electrically couple components of the circuitry to cause performance of operations. PCBs include conductive pads (contacts, terminals, etc.) to electrically couple the components of the circuitry to electrical traces, internal to the PCB. Solder electrically and mechanically couple circuitry to the conductive pads. Such a mounting may be referred to as surface mounting. The electrical traces route signals, power planes, and/or voltages between electrical components. Locations of the conductive pads may be constrained by the size of the components of the circuitry, conflicting locations of other components, electrical traces, etc.

IC packages typically include one or more semiconductor dies (also known as chips or chiplets) supported on a package substrate. The package substrate includes electrical traces to electrically couple the semiconductor dies on the substrate to the PCB on which the IC package is mounted. The semiconductor die(s) include semiconductor implementations of circuitry, such as programmable circuitry. As integrated circuitry continues to advance, IC packages include an increasing number of contacts to support additional operations of the associated semiconductor die(s) contained therein. As such, PCBs need to include a corresponding increase in the number contacts and associated traces to connect the IC packages to other electrical components on or coupled to the PCB. Further, in many instances the PCBs need to include an increasing number of electrical components for use in conjunction with the operation of the increasingly complex IC packages.

Designers allocate a region of the PCB for contacts (e.g., pads, balls, etc.) that are configured to be electrically coupled to contacts (e.g., a ball grid array (BGA), a land grid array (LGA), a pin grid array (PGA), etc.) of an IC package. A solder ball is placed on each of the contacts of such a region to electrically and mechanically couple the PCB to the package substrate. Such a region of the PCB including a plurality of contacts and solder bumps may be referred to as a solder bump region. As the number of contacts in the solder bump region of a PCB increases (based on an increase in contacts on the interfacing IC package), providing routing from the contacts in the solder bump region to other electrical components on the PCB becomes increasingly complex. The electrical traces resulting from such a routing through the solder bump region have excessive lengths and/or are exposed to radiated noise, such as noise from power planes, relatively high currents, etc. As signals traverse such traces, parasitic characteristics of the excessive length (e.g., a capacitance, resistance, etc.) and the radiated noise modify the signals. Exposing some signals, such as clock signals from timing circuitry, to such noise and/or parasitic characteristics may prevent circuitry of the IC package from operating as designed.

Examples disclosed herein include methods and apparatus to manage noise for timing circuitry. In some disclosed examples, a timing package is employed that is separate from the PCB and separate from an associated IC package. Although separate from the IC package, in some examples, the timing package is electrically coupled to the IC package independent of the PCB. That is, in some examples, the timing package includes contact that are electrical coupled with contacts on the IC package without the signal path passing through electrical traces in the PCB. Such a timing package reduces routing complexity of clock signals from timing circuitry to the IC package. The timing package allows for routing that decreases the length of the electrical traces that supply the clock signals to the package. Further, the timing package decreases an exposure of the clock signals to radiated noise by increasing separation between components and/or traces that emit noise and the traces of the timing package.

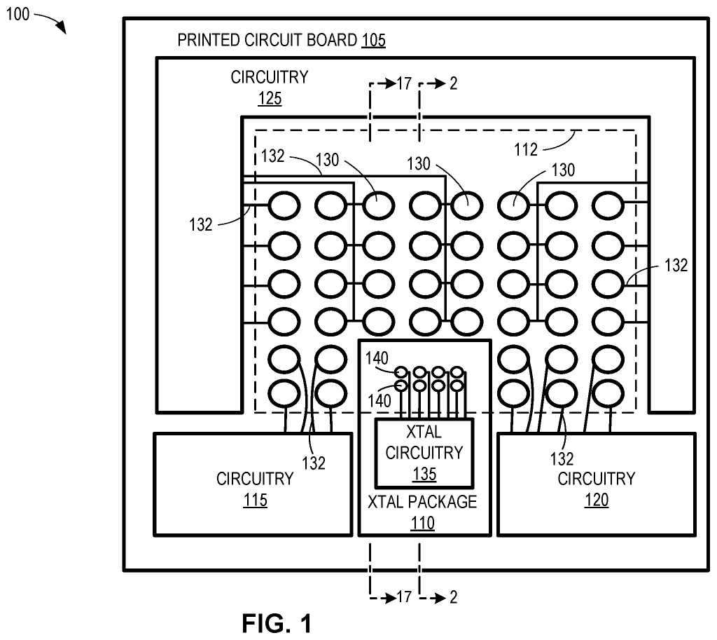

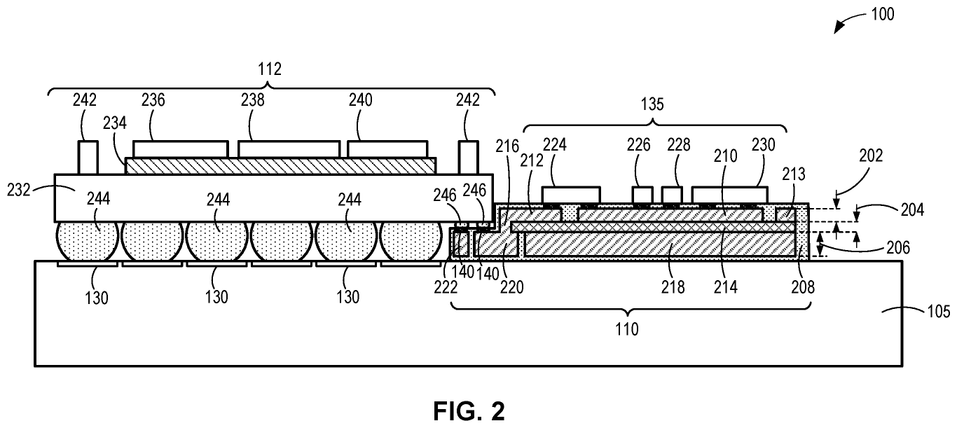

FIG. 1 is a block diagram of an example integrated circuit package assembly 100 including an example PCB 105, an example timing package 110, and an example IC package 112. In the example of FIG. 1, first example circuitry 115, second example circuitry 120, third example circuitry 125 are mounted on the PCB 105. In FIG. 1, the example IC package 112 is demarcated by dotted lines and otherwise invisible to show first example contacts (e.g., solder bumps, balls, contact pads, pins, etc.) 130 on the PCB 105 that electrically coupled the IC package 112 to the PCB 105. The electrical and mechanical coupling between the IC package 112 and the first contacts 130 is illustrated in the example implementation shown in FIG. 2.

The example PCB 105 includes a plurality of electrical traces. The traces electrically couple components of the example circuitries 115, 120, 125. A trace is an electrical interconnect between a first contact and a second contact of the example PCB 105. In some examples, the traces are made of copper. Alternatively, the example PCB 105 may be modified to include electrical traces manufactured using an alternative conductive material, such as gold. A designer and/or a design tool (e.g., an electronic design automation tool) generates a trace by routing a connection between two or more components through one or more layers of the example PCB 105. In the example of FIG. 1, example traces 132 between the circuitries 115, 120, 125 and the first contacts 130 are illustrated. Additionally or alternatively, the example PCB 105 may include traces between components of the circuitries 115, 120, 125.

In the illustrated example, the timing package 110 is labeled as an “XTAL package” to convey that the timing package 110 includes an XTAL component (e.g., a crystal oscillator component). The example timing package 110 is mechanically coupled to the PCB 105 without being electrically coupled to the PCB 105. That is, in some examples, unlike the IC package 112 that is electrically coupled to the PCB via the first contacts 130, there are no contacts (e.g., bumps) on the PCB 105 that are directly coupled to corresponding contacts of the timing package 110. In the example of FIG. 1, the timing package 110 includes example timing circuitry 135 and second example contacts (e.g., solder bumps, micro-balls, contact pads, pins, etc.) 140. The example timing package 110 is electrically coupled to the IC package 112 by the second contacts 140, as shown and described in further detail in connection with FIG. 2. The example timing package 110 is to generate and supply a clock signal to the IC package 112 by the second contacts 140. The second contacts 140 are independent of the first contacts 130. In some examples, the first contacts 130 are spaced apart from the timing circuitry 135 to reduce irradiated noise. In such examples, spacing apart the first contacts 130 reduces an exposure of irradiated noise from the timing circuitry 135 coupled to the second contacts 140. Advantageously, the example timing package 110 isolates the clock signal from radiated noise from the circuitries 115, 120, 125 and the associated traces 132 interconnecting the circuitries 115, 120, 125.

The example circuitries 115, 120, 125 include a plurality of electrical components (e.g., resistors, capacitors, amplifiers, logic devices, etc.). The example circuitries 115, 120, 125 are electrically coupled to the IC package 112 via the first contacts 130.

The example circuitries 115, 120, 125 radiate noise while in operation. The radiated noise of the example circuitries 115, 120, 125 depends on a power domain of the circuitries 115, 120, 125, the packaging of components, operational speeds, etc. The radiated noise of the example circuitries 115, 120, 125 is capable of increasing the signal to noise ratio (SNR) of nearby signals. In some examples, one or more of the circuitries 115, 120, 125 irradiate noise capable of distorting relatively low-power and/or relatively higher speed signals. In such examples, routing such a lower-power and/or relatively high-speed signal in proximity to the one or more circuitries 115, 120, 125 increases the SNR. For example, routing a relatively high-speed clock signal in proximity to (e.g., through, around, and/or near) regulator circuitry and/or traces from the regulator circuitry. In such an example, the regulator circuitry irradiates noise that is relatively small in comparison to the power supply signal but may be relatively high compared to a relatively high-speed clock signal. Advantageously, increasing the distance between the irradiated noise and signals of a relatively lower power and/or relatively higher speed decreases an impact of the irradiated noise.

The example timing circuitry 135 is to receive power and a common potential (e.g., ground) from the IC package 112. The example timing circuitry 135 generates a clock signal responsive to receiving the power and the common potential. In some examples, the timing circuitry 135 includes crystal oscillator circuitry capable of generating the clock signal responsive to supply power to a crystal. In such examples, characteristics of the crystal determine the frequency of the clock signal from the timing circuitry 135. In other examples, the timing circuitry 135 is an alternative type of oscillator circuitry, such as resistor-capacitor (RC) oscillator circuitry. The example timing circuitry 135 supplies the clock signal to the IC package 112 through the second contacts 140.

Advantageously, the timing package 110 reduces parasitic characteristics of the electrical traces of the timing circuitry 135 by reducing the length of the traces. Advantageously, positioning the timing circuitry 135 using the timing package 110 reduces exposure of clock signals to radiated emissions from components of the circuitries 115, 120, 125. Advantageously, the timing package 110 reduces the complexity of positioning the timing circuitry 135 around the circuitries 115, 120, 125.

FIG. 2 is a block diagram of an example cross-sectional view of an example implementation of the example integrated circuit package assembly 100 of FIG. 1 taken along the line 2-2 of FIG. 1. In the example of FIG. 2, the integrated circuit package assembly 100 includes the PCB 105 of FIG. 1, the timing package 110 of FIG. 1, and the example IC package 112. As shown in the illustrated example of FIG. 2, the timing package 110 is external to and distinct from the PCB 105 and the IC package 112.

In the example of FIG. 2, the timing package 110 includes the example timing circuitry 135 of FIG. 1, the second example contacts 140 of FIG. 1, a first example conductive layer 202, an example insulating layer 204, a second example conductive layer 206, an example mold layer 208, a first example trace 210, a second example trace 212, an example partial reference plane 213, an example dielectric 214, an example via 216, an example reference plane 218, a third example trace 220, and a fourth example trace 222. In the example of FIG. 2, the timing circuitry 135 includes a first example resistor 224, a second example resistor 226, an example capacitor 228, and an example oscillator component 230.

The first example conductive layer 202 is mechanically coupled between the timing circuitry 135 and the insulating layer 204. The first example conductive layer 202 is electrically coupled to the timing circuitry 135 and the via 216. Further, the first example conductive layer 202 creates a first surface of the timing package 110. The first surface of the timing package 110 is configured to be coupled to the timing circuitry 135. The first surface of the timing package 110 allows the traces 210, 212 to be electrically coupled to external circuitry. In some examples, the first surface of the timing package 110 is exposed through openings in the mold layer 208 that defines an exterior of the timing package 110.

In the example of FIG. 2, the first conductive layer 202 includes the first trace 210, the second trace 212, and the partial reference plane 213. The mold layer 208 forms around the first conductive layer 202 by enclosing (e.g., encapsulating, encases, surrounding) portions of the first trace 210, the second trace 212, and the partial reference plane 213. In some examples, the mold layer 208 encloses portions of the first conductive layer 202 not coupled to the insulating layer 204 and/or components of the timing circuitry 135.

The example insulating layer 204 is mechanically coupled between the first conductive layer 202 and the second conductive layer 206. In the example of FIG. 2, the insulating layer 204 includes the dielectric 214 and the via 216 extending through the dielectric 214 to electrically couple the second trace 212 and the third trace 220. The mold layer 208 forms around the insulating layer 204 by enclosing (e.g., encapsulating, encases, surrounding) portions of the dielectric 214 and the via 216. In some examples, the mold layer 208 encloses portions of the insulating layer 204 not coupled to the first conductive layer 202 and/or the second conductive layer 206.

The second example conductive layer 206 is mechanically coupled to the second contacts 140, the insulating layer 204, and the mold layer 208. The second example conductive layer 206 is electrically coupled to the second contacts 140 and the via 216. The second example conductive layer 206 is positioned to have the second contacts 140 face towards the IC package 112. Further, the second example conductive layer 206 defines a second surface of the timing package 110 where the second contacts 140 are located. In some examples, the second surface of the timing package 110 is exposed through openings in the mold layer 208 covering portions of the second surface. As shown in the illustrated example, the second surface of the timing package 110 is offset from the first surface of the timing package 110 in a direction normal to the PCB 105 on which the timing package 110 is mounted. That is, in this example, the second surface (containing the contacts 140) is closer to the PCB 105 than the first surface (containing the timing circuitry 135) is to the PCB 105. However, as shown in the illustrated example, the second contacts 140 are spaced apart from the PCB 105.

In the example of FIG. 2, the second conductive layer 206 includes the reference plane 218, the third trace 220, and the fourth trace 222. The mold layer 208 forms around the second conductive layer 206 by enclosing (e.g., encapsulating, encases, surrounding) portions of the reference plane 218, the third trace 220, and the fourth trace 222. In some examples, the mold layer 208 encloses portions of the second conductive layer 206 not coupled to the insulating layer 204 and/or the second contacts 140.

The example mold layer 208 is mechanically coupled to the layers 202, 204, 206. In the example of FIG. 2, the mold layer 208 is coupled to the PCB 105 to separate or isolate the conductive layers 202, 206 from the PCB 105. In some examples, the mold layer 208 is mechanically coupled to the PCB 105 by an adhesive. In such an example, the portion of the mold layer 208 coupled to the PCB 105 is devoid of conductive material. In other examples, the mold layer 208 is mechanically coupled to the PCB 105 by stand-offs. The example mold layer 208 is an encapsulant that defines the exterior of the timing package 110. In some examples, the mold layer 208 may be used to separate conductive components of the timing package 110, such as the traces 210, 212, 220, 222 and the reference planes 213, 218, from each and/or the PCB 105. The example mold layer 208 insulates the layers 202, 204, 206 from irradiated noise from circuitry of the PCB 105 (e.g., the circuitries 115, 120, 125 of FIG. 1 and/or traces within the PCB 105 that extend underneath where the timing package 110 is mounted).

The example traces 210, 212, 220, 222 are electrical interconnects configured to electrically couple one or more components and/or the reference plane 218. The example traces 210, 212, 220, 222 are constructed from a conductive material, such as copper, gold, aluminum, etc. In the example of FIG. 2, the traces 210, 212, 220, 222 are configured to route signals between the second contacts 140 and one or more components of the timing circuitry 135. For example, the traces 212, 220 and the via 216 allow the timing circuitry 135 to supply a clock signal (XTAL) to the IC package 112.

The example partial reference plane 213 is electrically coupled to the reference plane 218. The example partial reference plane 213 is configured to be coupled to a common potential (e.g., ground, a reference voltage, etc.). The example partial reference plane 213 is constructed from a conductive material, such as copper, gold, aluminum, etc.

In some examples, the traces 210, 212, 220, 222 are insulated from each other by a dielectric material, such as the mold layer 208 and/or the dielectric 214. For example, the mold layer 208 separates and insulates the first trace 210 from the second trace 212. In another example, the dielectric 214 separates and insulates the first trace 210 from the reference plane 218.

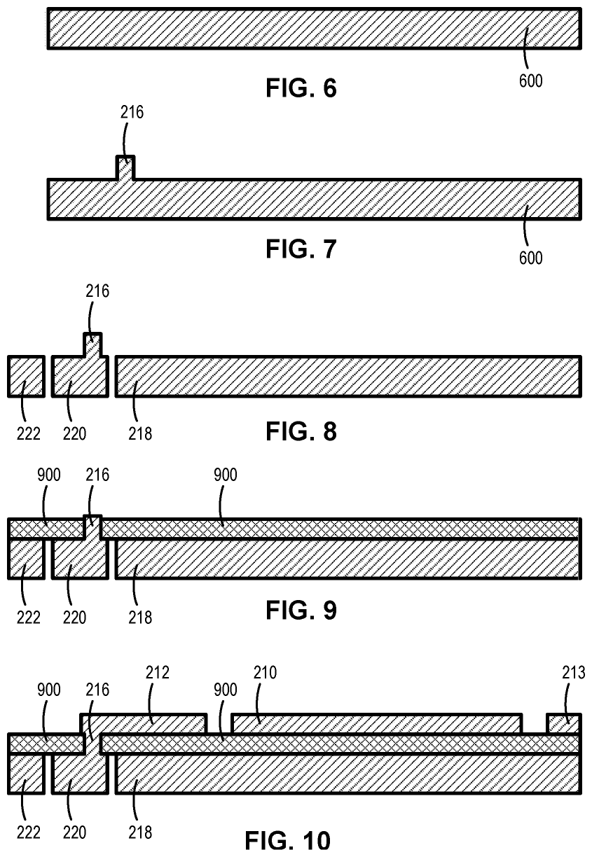

In such examples, insulating one or more of the traces 210, 212, 220, 222 from one another allows the one or more of the traces 210, 212, 220, 222 to be coupled to different voltages. For example, the first trace 210 represents the clock signal from the oscillator component 230. An example process for manufacturing the example timing package 110 with the traces 210, 212, 220, 222 is illustrated and described in connection with FIGS. 6-15.

The example dielectric 214 is mechanically coupled to the mold layer 208, the traces 210, 212, 220, the via 216, and the reference plane 218. The example dielectric 214 insulates the traces 210, 212 from the reference plane 218. The dielectric 214 is constructed from a dielectric material, such as epoxy, polyurethane, etc. The example dielectric 214 reduces interference between voltages of the traces 210, 212.

The example via 216 is mechanically coupled to the mold layer 208, the traces 212, 220, and the dielectric 214. The example via 216 electrically couples the second trace 212 to the third trace 220. The example via 216 allows signals to traverse the insulating layer 204. In some examples, the via 216 may be referred to as a trace. The example via 216 is constructed from a conductive material, such as copper, gold, aluminum, etc.

The example reference plane 218 is electrically coupled to the fourth trace 222. The example reference plane 218 is configured to be coupled to a common potential (e.g., ground, a reference voltage, etc.). The example reference plane 218 is constructed from a conductive material, such as copper, gold, aluminum, etc. An example top view of the reference plane 218 (along with the electrically coupled fourth trace 222) is illustrated in FIG. 5, below.

The first example resistor 224 has a first contact electrically coupled to the first trace 210. The first example resistor 224 has a second contact electrically coupled to the second trace 212. In some examples, the first resistor 224 limits a current supply to the first trace 210. In other examples, the first resistor 224 generates a voltage difference between the traces 210, 212. In such examples, the voltage difference sets a voltage of the first trace 210 to a logic level of the oscillator component 230.

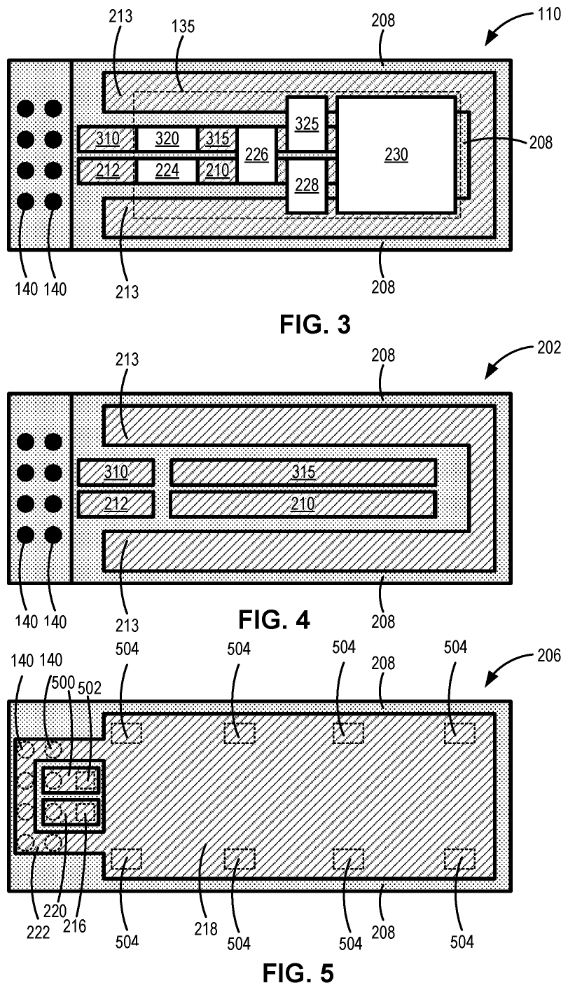

The second example resistor 226 has a first contact electrically coupled to the first trace 210. The second example resistor 226 has a second contact to be electrically coupled to another trace 315 (e.g., a sixth trace as shown in FIG. 3). In some examples, the second resistor 226 regulates a current. In other examples, the second resistor 226 generates a voltage difference. In such examples, the voltage difference sets a voltage of the first trace 210.

The example capacitor 228 has a first contact electrically coupled to the first trace 210. The example capacitor 228 has a second contact to be electrically coupled to a common contact that supplies a common potential (e.g., ground or a voltage source supply (Vss)). The example capacitor 228 stabilizes outputs of the oscillator component 230. In some examples, the capacitor 228 averages noise of a frequency relatively higher than an output of the oscillator component 230. In such examples, the capacitor 228 increases the accuracy of a clock signal from the oscillator component 230.

The example oscillator component 230 has a first contact and a second contact coupled to the first trace 210. The example oscillator component 230 has a third contact and a fourth contact to be electrically coupled to the sixth trace 315, as described in connection with FIG. 3. In some examples, the oscillator component 230 may have a contact configured to be coupled to the common potential. In the example of FIG. 2, the oscillator component 230 receives power from the first trace 210. The oscillator component 230 generates a clock signal based on an oscillation responsive to power from the first trace 210. In some examples, the oscillator component 230 supplies the clock signal by the third and fourth contacts to the sixth trace 315. In other examples, the oscillator component 230 differentially supplies the clock signal by the first trace 210 and the sixth trace 315. In some examples, the oscillator component 230 may be a crystal oscillator. In other examples, the oscillator component 230 may be a resistor capacitor oscillator.

In the example of FIG. 2, the IC package 112 includes an example package substrate 232 and an example base semiconductor die 234 on which is mount several other semiconductor dies. In this example, the other semiconductor dies include an example central processing unit (CPU) 236, an example system on chip (SoC) 238, an example graphics processing unit (GPU) 240. In some examples, the CPU 236, the SoC 238, and/or the GPU 240 may be described as hard intellectual property (IP) blocks. In such examples, the CPU 236, the SoC 238, and/or the GPU 240 may be components designed and/or manufactured separate of the IC package 112. In some examples, one or more of the base die 234, the CPU 236, the SoC 238, and the GPU 240 may be omitted and/or replaced with one or more other semiconductor dies. In this example, the IC package 112 includes example shielding 242 that surrounds the base die 234, the CPU 236, the SoC 238, and the GPU 240.

The example package substrate 232 includes third contacts (e.g., solder bumps, balls, contact pads, pins, etc.) 244 that are to be electrically and mechanically coupled to corresponding ones of the first contacts 130 on the PCB 105. Additionally, in this example, the package substrate 232 includes fourth contacts (e.g., solder bumps, balls, contact pads, pins, etc.) 246 that are to be electrically and mechanically coupled to corresponding ones of second contacts 140 on the timing package 110. The example package substrate 232 electrically couples the contacts 244, 246 to the base die 234 via traces and/or electrical routing through the package substrate 232. In some examples, the package substrate 232 includes a plurality of traces (not illustrated for simplicity) to electrically couple the contacts 130, 140 to the base die 234.

The example base die 234 is coupled between the package substrate 232 and the CPU 236, the SoC 238, and the GPU 240. The example base die 234 couples inputs and outputs of the CPU 236, the SoC 238, and the GPU 240 to the package substrate 232.

The example CPU 236 is mechanically and electrically coupled to the base die 234. The example CPU 236 is programmable circuitry configured to instantiate circuitry to perform operations responsive to machine-readable instructions. In some examples, traces of the PCB 105, the package substrate 232, and/or the base die 234 supply the machine-readable instructions to the CPU 236. In such examples, the CPU 236 supplies a result of performance of the operations to the PCB 105, the SoC 238, and/or the GPU 240 by the traces of the PCB 105, the package substrate 232, and/or the base die 234.

The example SoC 238 is mechanically and electrically coupled to the base die 234. The example SoC 238 is circuitry implemented using a semiconductor material. In some examples, the SoC 238 is circuitry implemented using static random-access memory (SRAM). In such examples, the circuitry of the SoC 238 is specific to the IC package 112. For example, the SoC 238 may be cache memory circuitry configured to support operations of the CPU 236 and/or the GPU 240.

The example GPU 240 is mechanically and electrically coupled to the base die 234. The example GPU 240 is programmable circuitry configured to instantiate circuitry to perform graphics operations responsive to machine-readable instructions. In some examples, traces of the PCB 105, the package substrate 232, and/or the base die 234 supply the machine-readable instructions to the GPU 240. In such examples, the GPU 240 supplies a result of performance of the operations to the PCB 105, the CPU 236, and/or the SoC 238 by the traces of the PCB 105, the package substrate 232, and/or the base die 234.

FIG. 3 is a schematic diagram of an example top view of the example timing package 110 of FIG. 2. For purposes of illustration, the portion of the mold layer 208 on the top surface of the timing package 110 has been removed to reveal the underlying first conductive layer 202 to which the components of the timing circuitry 135 are connected. A clearer view of the first conductive layer 202 (unobstructed by the components of the timing circuitry 135) is shown in FIG. 4. In the example of FIG. 3, the timing package 110 includes the timing circuitry 135, the mold layer 208, the first trace 210, the second trace 212, the partial reference plane 213, the first resistor 224, the second resistor 226, the capacitor 228, the oscillator component 230, a fifth example trace 310, a sixth example trace 315, a third example resistor 320, and a second example capacitor 325. In the example of FIG. 3, the timing circuitry 135 includes the resistors 224, 226, 320 the capacitors 228, 325, and the oscillator component 230.

The example traces 310, 315 are electrical interconnects configured to electrically couple one or more components. The example traces 310, 315, are constructed from a conductive material, such as copper, gold, aluminum, etc. In some examples, the traces 210, 212, 310, 315 are constructed by placing a conductive material on the dielectric 214. The example traces 310, 315 are similar to the traces 210, 212, 220, 222 of FIG. 2. In the example of FIG. 3, the traces 210, 212, 310, 315 are configured to route signals to and/or from the second contacts 140 of FIG. 2 to one or more components of the timing circuitry 135.

The third example resistor 320 has a first contact electrically coupled to the fifth trace 310. The third example resistor 320 has a second contact electrically coupled to the sixth trace 315. In some examples, the third resistor 320 limits a current supply to the sixth trace 315. In other examples, the third resistor 320 generates a voltage difference between the traces 310, 315. In some examples, the third example resistor 320 is similar to the first resistor 224.

The second example capacitor 325 has a first contact electrically coupled to the fifth trace 310. The second example capacitor 325 has a second contact electrically coupled to the partial reference plane 213 that supplies a common potential (e.g., ground or a voltage source supply (Vss)). The second example capacitor 325 stabilizes outputs of the oscillator component 230. In some examples, the second capacitor 325 averages noise of a frequency relatively higher than an output of the oscillator component 230. In such examples, the second capacitor 325 increases the accuracy of a clock signal from the oscillator component 230.

FIG. 4 is a schematic diagram of an example top view of the first conductive layer 202 of FIG. 2 of the timing package 110 of FIGS. 1-3. As shown in the illustrated example of FIG. 4, the first conductive layer 202 includes the mold layer 208, the first trace 210, the second trace 212, the dielectric 214, the partial reference plane 213, the fifth trace 310 of FIG. 3, and the sixth trace 315 of FIG. 3.

FIG. 5 is a schematic diagram of an example top view of the second conductive layer 206 of FIG. 2 of the timing package 110 of FIGS. 1-3. As shown in the illustrated example of FIG. 5, the second conductive layer 206 includes the mold layer 208, the reference plane 218, the third trace 220, the fourth trace 222, and a seventh example trace 500.

In the example of FIG. 5, the traces 220, 500 are to be coupled to the traces 212, 310. The fourth example trace 222 is configured to be coupled to a common potential. In some examples, the fourth trace 222 couples the reference plane 218 to the common potential of the IC package 112. In such examples, a portion of the second contacts 140 of FIG. 2 couple the fourth trace 222 to a common potential of the IC package 112. As discussed above, the traces 212, 220, 500 define the second surface of the timing package 110 on which the second contacts 140 are provided to enable the direct electrical coupling between the timing package 110 and the IC package 112 (as shown in FIG. 2). Specifically, in the illustrated example, the location of the second contacts 140 are represented by dotted circles upwards from which (e.g., out of the page from the perspective of the view shown in FIG. 5) the second contacts 140 extend. In this example, there are a total of eight contacts 140 with six of them positioned on the fourth trace 222 to interconnect the fourth trace 222 (and the associated reference plane 218) with a common potential of the IC package 112. Advantageously, the fourth trace 222 reduces radiated noise by surrounding the traces 220, 500 with the common potential. In the illustrated example, the two remaining contacts of the second contacts 140 are located on respective ones of the traces 220, 500. In some examples, a different number of the second contacts 140 may be used than what is shown in FIG. 5. Likewise, in some examples, the location of the second contacts 140 can differ from what is shown in FIG. 5.

In FIG. 5, the location of the via 216 is represented by a dotted square. As shown, the via 216 is located on the third trace 220 and positioned so as to extend upwards (e.g., out of the page from the perspective of FIG. 5) to couple with the second trace 212 (shown in FIG. 4). Further, in this example, a similar via 502 is positioned on the seventh trace 500 to electrically couple with the fifth trace 310 (shown in FIG. 4). Further, in this example, a plurality of additional vias 504 (e.g., at the locations represented by the dotted rectangles) are distributed along the reference plane 218 to electrically couple with the partial reference plane 213 (shown in FIG. 4).

In the examples of FIGS. 2-5, the reference planes 213, 218 have a relatively high inductance characteristic responsive to being constructed from a relatively large amounts of conductive material. Advantageously, the inductance of the reference planes 213, 218 is greater than an inductance characteristic of the traces 210, 212, 310, 315, 220, 500 responsive to the traces 210, 212, 310, 315, 220, 500 being constructed from relatively smaller amounts of conductive material. In some examples, placing the reference planes 213, 218 between surrounding circuitries and the traces 210, 212, 310, 315, 220, 500 reduces inductive coupling. In such examples, placing the relatively large inductance of the reference planes 213, 218 between the radiated noise and the traces 210, 212, 310, 315, 220, 500 reduces noise resulting from inductive coupling.

Further, coupling the reference planes 213, 218 and the fourth trace 222 to the common potential further reduces the impact of radiated noise on signals of the traces 210, 212, 310, 315, 220, 500. In some examples, exposing the common potential to the radiated noise allows both signals of a differential pair to be uniformly exposed to approximately the same noise. In such examples, using the difference between the signals of a differential pair as the clock signal removes uniform noise. For example, using the signals of the traces 220, 500 as the clock signal allows circuitry to remove noise induced in the common potential by taking the difference between the signals. Advantageously, exposing the common potential prevents the radiated noise from having a different impact on signals of the traces 210, 212, 310, 315, 220, 500. Advantageously, noise induced by the radiated noise may be removed from the clock signals of the timing package 110 by differentially comparing the clock signals.

FIGS. 6-14 are schematic diagrams representative of different stages of fabrication of the example timing package 110 of FIGS. 2-5.

FIG. 6 is a schematic diagram of an example copper foil layer 600 as a starting point in an example fabrication process for the timing package 110. The example copper foil layer 600 is a conductive base layer of the timing package 110 of FIGS. 2-5. In some examples, etching the copper foil layer 600 allows creation of traces (e.g., the traces 220, 222 of FIGS. 2 and 5. In some examples, the copper foil layer 600 has a thickness that is smaller than the size of the third contacts 244 on the IC package 112 to fit underneath the package substrate 232 of the package 112 (e.g., between the package substrate 232 and the PCB 105). For example, the copper foil layer 600 may have a thickness of approximately two-tenths of an inch (in). In some examples, a total thickness of the timing package 112 may be up to one to two ounces (Oz). In such an example, half an ounce of copper corresponds to a thickness of approximately six-tenths of an inch. Although in the example of FIG. 6, the copper foil layer 600 is manufactured using copper, alternative conductive materials may be used in accordance with the teachings described herein, such as gold, aluminum, etc.

FIG. 7 is representative of the stage in the example fabrication process after the addition of the example via 216 of FIG. 2 onto the copper foil layer 600 of FIG. 6. The example via 216 is to electrically couple the copper foil layer 600 to other conductive materials/layer/traces of the timing package 110 of FIGS. 2-5. In some examples, one or more other vias (e.g., the vias 502, 504 shown in FIG. 5) are added to the copper foil layer 600. In such examples, each of the other vias 502, 504 are configured to couple one or more traces and/or reference planes of the copper foil layer 600 to one or more layers of the timing package 110. For instance, as discussed above, the via 216 of FIG. 2 is to extend between and connect the third trace 220 in the second conductive layer 206 and the second trace 212 in the first conductive layer 202. However, in some examples, a separate via is provided to extend between and connect the seventh trace 500 (FIG. 5) in the second conductive layer 206 and the fifth trace 310 (FIGS. 3 and 4) in the first conductive layer 202. Furthermore, in some examples, one or more additional vias are provided to extend between and connect the reference plane 218 (FIGS. 2 and 5) in the second conductive layer 206 and the partial reference plane 213 (FIGS. 2-4). For example, the vias 1700 of FIG. 17, below. In some examples, these vias are added to the copper foil layer 600 by depositing and then patterning a dry film resist with openings at the locations for the vias, plating (e.g., electrolytic plating) metal (e.g., copper) within the openings to produce the vias, and then removing the dry film resist.

FIG. 8 is representative of the stage in the example fabrication process after an example etching process of the copper foil layer 600 of FIG. 7. In the example of FIG. 8, the etching process defines the reference plane 218 and the traces 220, 222 shown and described above in connection with FIGS. 2 and 5.

FIG. 9 is representative of the stage in the example fabrication process after the addition of an example dielectric layer 900 onto the reference plane 218 and the traces 220, 222 of the copper foil 600. The example dielectric layer 900 is an insulating material that serves as the basis for the dielectric 214 shown in FIG. 2. The example dielectric layer 900 electrically isolates the reference plane 218 and the traces 220, 222 from traces and/or planes placed on top of the dielectric layer 900. In some examples, the dielectric layer 900 encloses the vias 216, 502, 504, while leaving one or more surfaces of the vias 216, 502, 504 exposed. In such examples, the one or more exposed surfaces of the via 216 allow alternative traces to be electrically coupled to the reference plane 218 and/or the traces 220, 222. That is, as shown in the illustrated example, the dielectric layer 900 has a thickness corresponding to the height of the vias 216, 502, 504 (and any other vias) so that the vias 216, 502, 504 extend through the dielectric layer 900. In some examples, the dielectric layer 900 is provided before the vias 216, 502, 504 and the vias 216, 502, 504 are added through a plating process in an opening provided in the dielectric layer 900. In some examples, the dielectric layer 900 is added through a lamination process.

FIG. 10 is representative of the stage in the example fabrication process after the addition of traces onto the dielectric layer 900 of FIG. 9. The traces added in FIG. 10 correspond to the traces in the first conductive layer 202 shown in FIGS. 2-4. Specifically, the traces include the traces 210, 212, 315 shown in FIGS. 3 and 4. Further, the partial reference plane 213 of FIGS. 2-4 is added in FIG. 10. Only the traces 210, 212 are shown in the illustrated example of FIG. 10. One or more of the example traces 210, 212, 310, 315 and the partial reference plane 213 are electrically coupled to one or more of the traces 220, 222 and the reference plane 218 by the vias 216, 502, 504. In some examples, one or more of the traces 210, 212, 310, 315 and the partial reference plane 213 may be coupled to one or more vias (e.g., the via 216) to supply one or more potentials to the first conductive layer 202. For example, the vias 216, 502 may route timing signals to/from the first conductive layer 202, while the vias 504 may route a common potential (e.g., ground, VSS) to/from the first conductive layer 202. In some examples, the traces 210, 212, 310, 315 and the partial reference plane 213 added at FIG. 10 are added by first implementing an electroless plating process followed by the deposition and patterning of a dry film resist. Thereafter, an electrolytic plating process is implemented to fill openings patterned in the dry film resist before the dry film resist is removed.

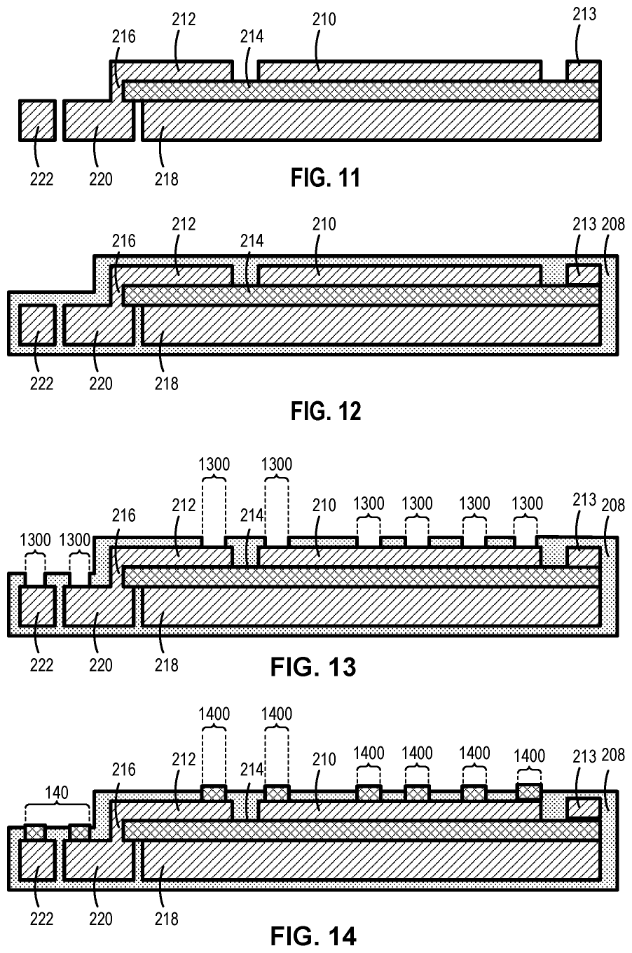

FIG. 11 is representative of the stage in the example fabrication process after the removal or trimming of the dielectric layer 900 to define the dielectric 214 of FIG. 2. Trimming the example dielectric layer 900 exposes one or more of the traces 220, 222 of FIGS. 2, 5, and 8-10. Once exposed, the traces 220, 222 may be electrically coupled to other components and/or traces. For example, the second contacts 140 of FIG. 2 electrically couple the traces 220, 222 to the package substrate 232 of FIG. 2. In some examples, the dielectric layer 900 is trimmed or removed using a laser.

FIG. 12 is representative of the stage in the example fabrication process after the addition of the mold layer 208 of FIGS. 2-5. In the example of FIG. 12, the mold layer 208 encloses the conductive layers 202, 206 and the insulating layer 204 to define an exterior surface for the timing package 110. The example mold layer 208 insulates the timing package 110 of FIGS. 2-5 from irradiated noise from surrounding circuitry (e.g., the circuitries 115, 120, 125 of FIG. 1). In some examples, the thickness and/or material of the mold layer 208 may be determined based on characteristics of the irradiated noise. For example, the thickness of the mold layer 208 may be increased to compensate for a placement of the timing package 110. In such an example, designers may increase the thickness of the mold layer 208 responsive to placements near a relatively noisy and/or relatively high-power portion of the PCB 105, such as regulator circuitry.

FIG. 13 is representative of the stage in the example fabrication process after the creation of example openings 1300 in the mold layer 208. The example openings 1300 expose portions of the conductive layers 202 and 206 of FIGS. 2, 4, and 5. The example openings 1300 allow the traces 210, 212, 220, 222, 310, 315, 500 of FIGS. 2-5, and 8-12 to be electrically coupled to the timing circuitry 135 of FIGS. 2-5 and/or the package substrate 232 of the IC package 112. In some examples, a first number of the openings 1300 is based on the number of signals coming to/from the timing package 110 of FIGS. 1-3. In such examples, a second number of the openings 1300 is based on the number of connections needed to electrically couple the timing circuitry 135 to the timing package 110. In some examples, the openings 1300 are provided by removing the material of the mold layer 208 with a laser.

FIG. 14 is representative of the stage in the example fabrication process after the addition of the second contacts 140 of FIG. 2 and example timing circuitry contacts 1400. In some examples, the contacts 140, 1400 are micro-balls (e.g., uBGA balls) attached to the exposed portions of the traces 210, 212, 220, 222, 310, 315, 500 in the openings 1300. The second example contacts 140 are to electrically couple the timing package 110 of FIGS. 1-3 to the package substrate 232 of FIG. 2. The example timing circuitry contacts 1400 are to electrically couple the timing package 110 of FIGS. 1-3 to the components of timing circuitry 135. That is, following the stage of fabrication represented in FIG. 14, the components of the timing circuitry 135 are attached to the timing circuitry contacts to complete the fabrication of the timing package 110 (as shown in FIG. 2.

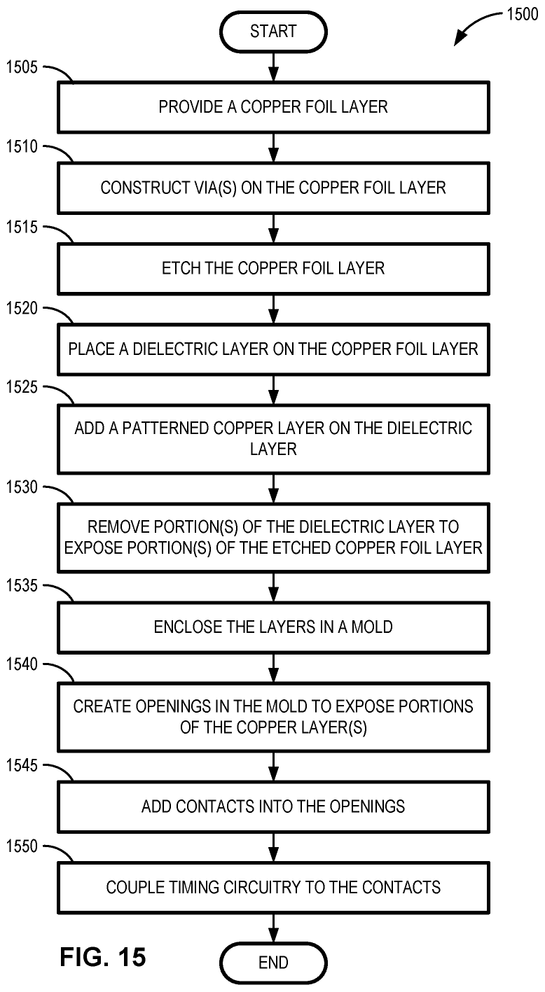

FIG. 15 is a flowchart representative of example operations 1500 that, when performed, produce the timing package 110 of FIGS. 2-5. In some examples, some or all of the operations outlined in the FIG. 15 are performed automatically by fabrication equipment that is programmed to perform the operations. The operations 1500 of FIG. 15 begin at Block 1505, at which a copper foil layer is provided. For example, the copper foil layer 600 of FIG. 6. Control proceeds to Block 1510.

At Block 1510, the example operations 1500 include constructing via(s) (e.g., the vias 216, 502, 504 of FIGS. 2, 5, and 7) on the copper foil layer. In some examples, one or more copper vias are constructed to traverse one or more layers of the timing package 110. For example, constructing the vias 216, 502, 504 on the copper foil layer 600 as discussed above in connection with FIG. 7. Control proceeds to Block 1515.

At Block 1515, the example operations 1500 include etching the copper foil layer. In some examples, the copper foil layer 600 is etched to create or define one or more individual traces (e.g., the traces 220, 222 of FIGS. 2, 5, and 8). For example, etching the copper foil layer 600 to create the traces 220, 222 as discussed above in connection with FIG. 8. Control proceeds to Block 1520.

At Block 1520, the example operations 1500 include placing a dielectric layer on the copper foil layer. In some examples, the dielectric layer 900 encloses sides of the vias 216, 502, 504. For example, placing the dielectric layer 900 on the reference plane 218, the traces 220, 222 and around the vias 216, 502, 504 as discussed above in connection with FIG. 9. Control proceeds to Block 1525.

At Block 1525, the example operations 1500 include adding a patterned copper layer on the dielectric layer. In such examples, the pattern of the first conductive layer 202 corresponds to the traces 210, 212, 310, 315 and the partial reference plane 213 as discussed above in connection with FIG. 10. Control proceeds to Block 1530.

At Block 1530, the example operations 1500 include removing portion(s) of the dielectric layer to expose portion(s) of the etched copper foil layer. In some examples, the dielectric layer 900 is trimmed with a laser to expose the traces 220, 222, 500. For example, trimming the dielectric layer 900 to create the dielectric 214 as discussed above in connection with FIG. 11. Control proceeds to Block 1535.

At Block 1535, the example operations 1500 include enclosing the layers in a mold. In some examples, the conductive layers 202, 206 and the insulating layer 204 are enclosed (e.g., encapsulated, encased) in the mold layer 208 of FIGS. 2-5 and 12-14. For example, enclosing the traces 210, 212, 220, 222, 310, 315, the dielectric 214, the vias 216, 502, 504, the reference plane 218, and the partial reference plane 213 with the mold layer 208, as discussed above in connection with FIG. 12. Control proceeds to Block 1540.

At Block 1540, the example operations 1500 include creating openings in the mold to expose portions of the copper layer(s). In some examples, the openings 1300 of FIG. 13 in the mold layer 208 are created (e.g., via laser etching) to expose portions of the conductive layers 202, 206. For example, creating the openings 1300 in the mold layer 208 to expose the traces 210, 212, 220, 222, 310, 315, as discussed above in connection with FIG. 13, above. Control proceeds to Block 1545.

At Block 1545, the example operations 1500 include adding contacts into the openings. In some examples, the contacts are solder bumps and/or micro-balls, but other types of contacts may alternatively be used. In some examples, the contacts are attached to the exposed portions of the conductive layers 202, 206 in the openings 1300 to create contacts that enable the electrically coupling of the conductive layers 202, 206 to the timing circuitry 135 and/or the package substrate 232 of the IC package 112. For example, adding contacts to the openings 1300 produce the second contacts 140 and the timing circuitry contacts 1400 as discussed above in connection with FIG. 14. Alternatively, the openings 1300 may be modified to allow alternative types of contacts to be used, such as free flow solder. Control proceeds to Block 1550.

At Block 1550, the example operations 1500 include coupling timing circuitry to the micro-balls. In some examples, the components of the timing circuitry 135 are coupled to the timing circuitry contacts 1400. For example, the resistors 224, 226, 320, the capacitors 228, 325, and the oscillator component 230 are electrically and mechanically attached to the timing circuitry contacts 1400 as shown in FIGS. 2 and 3. Control proceeds to End.

Although example processes are described with reference to the flowchart illustrated in FIG. 15, many other methods of manufacturing the timing package 110 may alternatively be used in accordance with teachings of this disclosure. For example, the order of execution of the blocks may be changed, and/or some of the blocks described may be changed, eliminated, or combined. Similarly, additional operations may be included in the manufacturing process before, in between, or after the blocks shown in the illustrated examples.

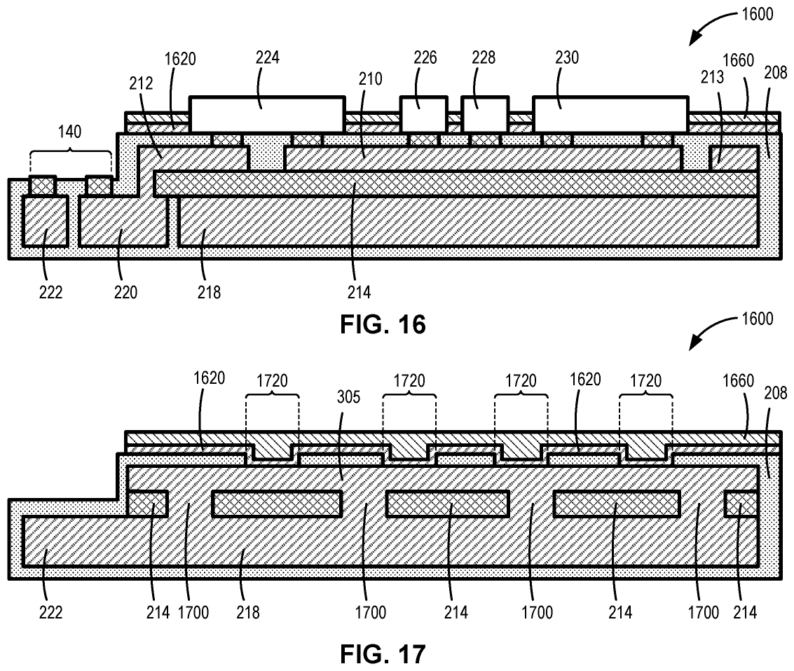

FIG. 16 is a block diagram of an example cross-sectional view of an example timing package 1600 taken along line 2-2 of FIG. 1. The timing package 1600 is another example implementation of the timing package 110 of FIG. 1. In the example of FIG. 16, the timing package 1600 includes the second contacts 140, the mold layer 208, the traces 210, 212, 220, 222, the dielectric 214, the via 216, the reference plane 218 the resistors 224, 226, the capacitor 228, the oscillator component 230, an example conductive coating 1620, and an example solder resist layer 1660. In the example of FIG. 16, the partial reference plane 213 (illustrated in FIG. 17), the reference plane 218, and the fourth trace 222 are configured to be coupled to the common potential.

The example conductive coating 1620 is mechanically coupled between the mold layer 208 and the solder resist layer 1660. The example conductive coating 1620 is to be coupled to a common potential (e.g., ground or a voltage source supply (Vss)). In some examples, the conductive coating 1620 is coupled to the partial reference plane 213, which supplies the common potential. In some examples, the conductive coating 1620 is a relatively thin copper layer (e.g., less than or equal to 1 μm, less than or equal to 0.8 μm, less than or equal to 0.6 μm, etc.). In such examples, an addition of the conductive coating 1620 negligibly changes a profile of the timing package 110. The example conductive coating 1620 coats portions of the mold layer 208 coupled between the traces 210, 212 and the timing circuitry 135. The example conductive coating 1620 reduces impacts of radio frequency interference (RFI) on the timing circuitry 135. Advantageously, the example conductive coating 1620 increases RFI immunity without excessively increasing the height of the timing package 110.

The example solder resist layer 1660 is mechanically coupled to the conductive coating 1620. The example solder resist layer 1660 coats the conductive coating 1620. The example solder resist layer 1660 prevents the conductive coating 1620 from allowing solder to free flow. Such a free flow of solder may short the traces 210, 212 and/or the partial reference plane 213. The example solder resist layer 1660 allows the conductive coating 1620 to be placed on the mold layer 208 without compromising the electrical connections of the timing circuitry 135. Advantageously, the solder resist layer 1660 allows for a placement of the conductive coating 1620 on the mold layer 208 without excessively increasing the height of the timing package 110. In some examples, the solder resist layer 1660 is added as a continuous layer of material across the timing package 1600 through a lamination process. In such examples, portions of the solder resist layer are removed to expose the underlying layers, thereby enabling the components of the timing circuitry 135 to be electrically and mechanically coupled to the timing package 1600. More particularly, in some examples, as shown in FIG. 16, the solder resist layer 1660 does not extend underneath the circuitry components 224, 226, 228, 230 because it was removed during a solder resist removal (e.g., stripping) process. That is, the portions of the solder resist layer 1660 that are removed corresponding to the footprint or size and shape of the circuitry components as shown and described in connection with FIG. 15.

FIG. 17 is a block diagram of an example cross-sectional view of the example timing package 1600 of FIG. 16 taken along line 17-17 of FIG. 1. In the example of FIG. 17, the timing package 1600 includes the second contacts 140, the mold layer 208, the fourth trace 222, the dielectric 214, the via 216, the reference plane 218, the conductive coating 1620, the solder resist layer 1660, and example vias 1700.

In the example of FIG. 17, the conductive coating 1620 encloses portions of the mold layer 208 to be electrically coupled to the partial reference plane 213, which provides the common potential. In some examples, the conductive coating 1620 is electrically coupled to the partial reference plane 213 through openings 1720 in the mold layer 208 aligned with the partial reference plane 213. In some examples, the openings 1720 are created at the same time (e.g., during the same fabrication process) as the openings 1300 of FIG. 13, as described in Block 1540 of FIG. 15. In such examples, creating the openings 1720 to electrically couple the conductive coating 1620 to the partial reference plane 213 at the same time as the openings 1300 reduces complexity. In such examples, the conductive coating 1620 may not only enter the openings 1720 to enabling the electrical coupling with the partial reference plane 213, but the conductive coating 1620 may also enter the openings 1300 intended for contact points for the components of the timing circuitry 135. Accordingly, in some examples, a subsequent etching process is selectively applied (via a patterned dry film resist) to remove portions of the conductive coating 1620 associated with the openings 1300 used to connect the components of the timing circuitry 135 to the traces 210, 212. Further in some examples, the selective etching process may also remove the conductive coating 1620 across a surface of the mold layer 208 corresponding to the footprint or size and shape of the different timing circuitry components to be attached as discussed in connection with FIG. 15. Alternatively, in some examples, the conductive coating 1620 may receive the common potential by being coupled to one or more vias extending through the mold layer 208.

The example vias 1700 are mechanically coupled to the reference planes 213, 218 and the dielectric 214. The example vias 1700 electrically couples the reference plane 218 to the partial reference plane 213. The example vias 1700 allow signals to vertically traverse the dielectric 214. In some examples, the vias 1700 may be referred to as traces. The example vias 1700 are constructed from a conductive material, such as copper, gold, aluminum, etc.

In the example of FIG. 17, the openings 1720 expose portions of the mold layer 208. In some examples, the example openings 1720 extend through both the mold layer 208 and the conductive coating 1620 to expose contacts of the timing package 1600. The example openings 1720 expose portions of the patrial reference plane 213. In the example of FIG. 17, the conductive coating 1620 is electrically coupled to the partial reference plane 213 through the openings 1720.

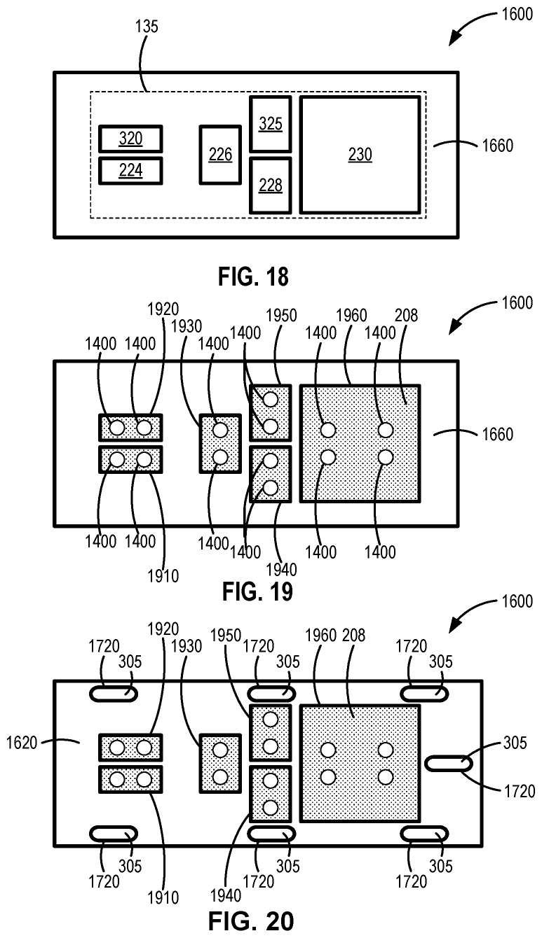

FIG. 18 is a schematic diagram of an example top view of the example timing package 1600 of FIGS. 16 and 17. In the example of FIG. 18, the timing package 1600 includes the timing circuitry 135, the resistors 224, 226, 320, the capacitors 228, 325, the oscillator component 230, and the solder resist layer 1660.

FIG. 19 is a schematic diagram of an example top view of the timing package 1600 of FIGS. 16, 17, and 18 without the timing circuitry 135. In the example of FIG. 19, the timing package 1600 includes the mold layer 208, the circuitry contacts 1400, the solder resist layer 1660, a first example opening 1910, a second example opening 1920, a third example opening 1930, a fourth example opening 1940, a fifth example opening 1950, and a sixth example opening 1960.

The example openings 1910, 1920, 1930, 1940, 1950, 1960 expose portions of the mold layer 208 and the circuitry contacts 1400. The portions of the mold layer 208, exposed by the openings 1910, 1920, 1930, 1940, 1950, 1960, are determined based on packaging of components of the timing circuitry 135. In some examples, the solder resist layer 1660 exposes portions of the mold layer 208 to prevent the packaging of the timing circuitry 135 from being on top of the solder resist layer 1660. For example, the first opening 1910 has a size and shape approximately equal to the first resistor 224 and the other openings 1920, 1930, 1940, 1950, 1960 are similarly sized and shaped in accordance with the corresponding components of the timing circuitry 135. Advantageously, the openings 1910, 1920, 1930, 1940, 1950, 1960 reduce complexity in coupling the timing circuitry 135 to the timing package 1600.

FIG. 20 is a schematic diagram of an example top view of the timing package 1600 of FIGS. 16 and 17 without the timing circuitry 135 and without the solder resist layer 1660. In the example of FIG. 19, the timing package 1600 includes the mold layer 208, the partial reference plane 213, the circuitry contacts 1400, the conductive coating 1620, the openings 1720, and the openings 1910, 1920, 1930, 1940, 1950, 1960.

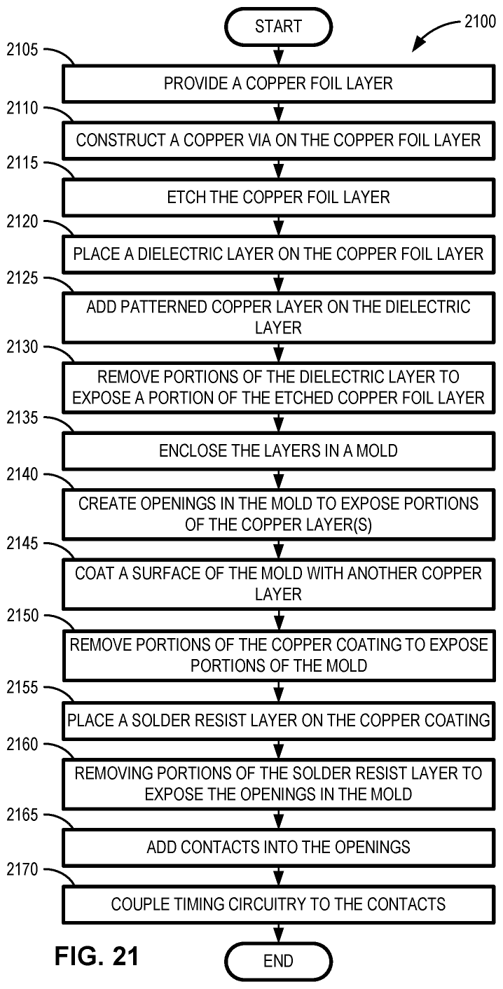

FIG. 21 is a flowchart representative of example operations 2100 that, when performed, produce the timing package 1600 of FIGS. 16-20. In some examples, some or all of the operations outlined in the FIG. 21 are performed automatically by fabrication equipment that is programmed to perform the operations. The operations 2100 of FIG. 21 begin at Block 2105 and process through Block 2140 in the same manner as Blocks 1505 through Block 1540 described above in connection with FIG. 15. The only difference with FIG. 15 up to this point in the process is in connection with Block 2140. In particular, in addition to creating the openings 1300 (as discussed above in connection with Block 1540 of FIG. 15), Block 2140 of FIG. 21 also includes creating the openings 1720 shown in FIG. 17. Following Block 2140, control proceeds to Block 2145.

At Block 2145, the example operations 2100 include coating a surface of the mold with another copper layer. In some examples, the copper layer is added using an electroless plating process. Using such a process, the copper layer will coat the insides of the openings 1300, 1720 created at Block 1540. In some examples, coating portions of the mold layer 208 with copper serves as the basis for the conductive coating 1620 of FIGS. 16, 17, and 20. Control proceeds to Block 2150.

At Block 2150, the example operations 2100 include removing portions of the copper coating to expose portions of the mold. In some examples, the exposed portions of the mold (e.g., the mold layer 208) correspond to the openings 1300 and the surrounding areas (e.g., the openings 1910, 1920, 1930, 1940, 1950, 1960 shown in FIG. 20) associated with the sizes and shapes of the components of the timing circuitry 135. In some examples, such portions of the copper coating are removed by patterning a dry film resist, etching the portions of the copper coating (e.g., the conductive coating 1620) exposed through patterned openings in the dry film resist, and then removing the dry film resist. Control proceeds to Block 2155.

At Block 2155, the example operations 2100 include placing a solder resist layer on the copper coating. In some examples, the solder resist layer is added through a lamination process such that the solder resist layer also covers the portions of the mold layer exposed at block 2150. Control proceeds to Block 2160.

At Block 2160, the example operations 2100 include removing portions of the solder resist layer to expose the openings in the mold previously uncovered at Block 2150. In some examples, this process is accomplished by lithographically patterning the solder resist layer and removing (e.g., stripping away) the relevant portions of the solder resist layer. Control proceeds through Blocks 2165 and 2170, which correspond to Blocks 1545 and 1550 of FIG. 15. Following Block 2170, control proceeds to End.

Although example processes are described with reference to the flowchart illustrated in FIG. 21, many other methods of creating the timing package 1600 may alternatively be used in accordance with teachings of this disclosure. For example, the order of execution of the blocks may be changed, and/or some of the blocks described may be changed, eliminated, or combined. Similarly, additional operations may be included in the manufacturing process before, in between, or after the blocks shown in the illustrated examples.

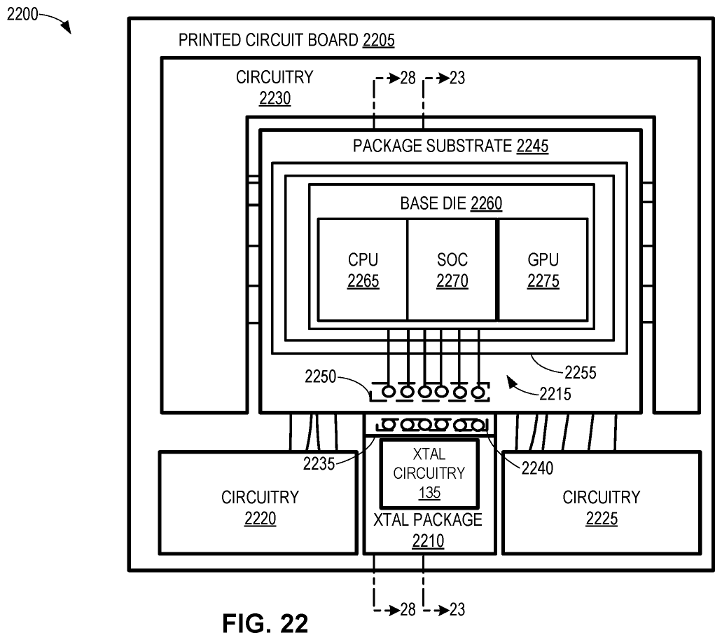

FIG. 22 is a block diagram of another example integrated circuit package assembly 2200 including an example PCB 2205, an example timing package 2210, and an example IC package 2215. In the example of FIG. 22, the timing package 2210 supplies a clock signal (XTAL) to the IC package 2215.

In the example of FIG. 22, the PCB 2205 includes first example circuitry 2220, second example circuitry 2225, and third example circuitry 2230. The PCB 2205 is coupled adjacent to the timing package 2210. In the example of FIG. 22, the timing package 2210 includes the timing circuitry 135 of FIGS. 2-3,16, and 18, and an example protrusion 2235 on which are positioned fifth example contacts (e.g., solder bumps, balls, contact pads, pins, etc.) 2240. In the example of FIG. 22, the IC package 2215 includes an example package substrate 2245, sixth example contacts (e.g., solder bumps, balls, contact pads, pins, etc.) 2250, example shielding 2255, an example base die 2260, an example CPU 2265, an example SoC 2270, and example GPU 2275.

The example PCB 2205 interconnects the circuitries 2220, 2225, 2230 to and/or from the IC package 2215 using electrical traces. The example circuitries 2220, 2225, 2230 are similar to the circuitries 115, 120, 125 of FIG. 1.

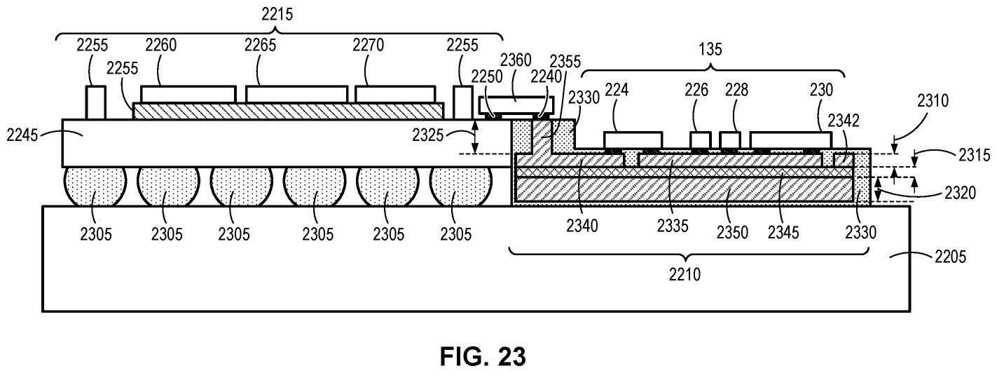

The example protrusion 2235 protrudes away from the surface of the timing package 2210 on which the timing circuitry 135 is mounted (as shown more clearly in FIG. 23).

The fifth example contacts 2240 are coupled to traces of the timing package 2210 by the protrusion 2235 forming a vertical interconnect. The fifth example contacts 2240 are to be electrically coupled to the IC package 2215 by example interconnects or components that span the distance between the contacts 2240, 2250, as shown in FIG. 23. In some examples, the fifth contacts 2240 are relatively small amounts (e.g., globs) of solder. In some such examples, surface tension of solder comprising the fifth contacts 2240 result in a ball shape. Alternatively, the timing package 2210 may be modified in accordance with the teachings described herein to utilize alternative type of solder, such as free flow solder or micro balls. In the example of FIG. 22, the fifth example contacts 2240 are to be coupled to an opposite side of the IC package 2215 compared to a side of the IC package 112 of FIG. 2 to be coupled to the second contacts 140. That is, in this example, the sixth contacts 2250 on the IC package 2215 on a surface of the package 2215 facing away from the PCB 2205.

The example package substrate 2245 is mechanically coupled to the PCB 2205, the sixth contacts 2250, the shielding 2255, and the base die 2260. The example package substrate 2245 is electrically coupled to the PCB 2205, the sixth contacts 2250, and the base die 2260. In the example of FIG. 22, the package substrate 2245 has the sixth contacts 2250 on a surface approximately flush to the fifth contacts 2240 of the timing package 2210. As used herein, two surfaces are “approximately flush” when the surfaces are flush with one another to within six one-hundredths of an inch (in). The example package substrate 2245 has electrical traces that electrically couple the sixth contacts 2250 to the base die 2260. In some examples, the example package substrate 2245 of FIG. 22 is similar to the package substrate 232 of FIG. 2.

The sixth example contacts 2250 are electrically coupled to the timing circuitry 135 by traces of the timing package 2210, as shown in FIG. 23, below. In some examples, the sixth contacts 2250 are relatively small amounts (e.g., globs) of solder. In some such examples, surface tension of solder comprising the sixth contacts 2250 result in a ball shape. Alternatively, the IC package 2215 may be modified in accordance with the teachings described herein to utilize alternative types of contacts, such as free flow solder or micro balls.

The example shielding 2255 is mechanically coupled to the package substrate 2245. In some examples, the example shielding 2255 of FIG. 22 is similar to the shielding 242 of FIG. 2.

The example base die 2260 is electrically and mechanically coupled to the package substrate 2245, the CPU 2265, the SoC 2270, and the GPU 2275. In some examples, the example base die 2260 of FIG. 22 is similar to the base die 234 of FIG. 2.

The example CPU 2265 is electrically and mechanically coupled to the base die 2260. In some examples, the example CPU 2265 of FIG. 22 is similar to the CPU 236 of FIG. 2.

The example SoC 2270 is electrically and mechanically coupled to the base die 2260. In some examples, the example SoC 2270 of FIG. 22 is similar to the SoC 238 of FIG. 2.

The example GPU 2275 is electrically and mechanically coupled to the base die 2260. In some examples, the example GPU 2275 of FIG. 22 is similar to the GPU 2275 of FIG. 2.

FIG. 23 is a block diagram of an example cross-sectional view of an example implementation of the example integrated circuit package assembly 2200 of FIG. 22 taken along line 23-23 of FIG. 22. In the example of FIG. 23, the integrated circuit package assembly 2200 includes the PCB 2205, the timing package 2210, and the IC package 2215.

In the example of FIG. 23, the PCB 2205 includes seventh example contacts (e.g., solder bumps, balls, contact pads, pins, etc.) 2305. The example seventh contacts 2305 electrically and mechanically couples the PCB 2205 to the package substrate 2245 of FIG. 22. In some examples, the seventh contacts 2305 are relatively small amounts (e.g., globs) of solder. In some such examples, surface tension of solder comprising the seventh contacts 2305 result in a ball shape. Alternatively, the PCB 2205 may be modified in accordance with the teachings described herein to utilize alternative types of contacts, such as free flow solder or balls in a ball grid array.

In the example of FIG. 23, the timing package 2210 includes the example timing circuitry 135, the fifth contacts 2240, a first example conductive layer 2310, an example insulating layer 2315, a second example conductive layer 2320, a third example conductive layer 2325, an example mold layer 2330, a first example trace 2335, a second example trace 2340, an example partial reference plane 2342, an example dielectric 2345, an example reference plane 2350, and a third example trace 2355. In the example of FIG. 23, the timing package 2210 is electrically coupled to the IC package 2215 by example resistor interconnects 2360 electrical coupled to the fifth contacts 2240 (on the timing package 2210) and the sixth contacts 2250 (on the IC package 2215).

The first example conductive layer 2310 is mechanically coupled between the timing circuitry 135 and the insulating layer 2315. The first example conductive layer 202 is electrically coupled to the timing circuitry 135 and the third trace 2355. In the example of FIG. 23, the first conductive layer 2310 includes the first trace 2335, the second trace 2340, and the partial reference plane 2342. The first conductive layers 2310 includes additional traces not shown in FIG. 23 but shown in FIG. 25. In some examples, the first conductive layer 2310 of FIG. 23 is similar in function and/or layout to the first conductive layer 202 of FIGS. 2 and 4.

The example insulating layer 2315 is mechanically coupled between the first conductive layer 2310 and the second conductive layer 2320. In the example of FIG. 23, the insulating layer 2315 includes the dielectric 2345. In some examples, the insulating layer 2315 of FIG. 23 is similar to the insulating layer 204 of FIG. 2.

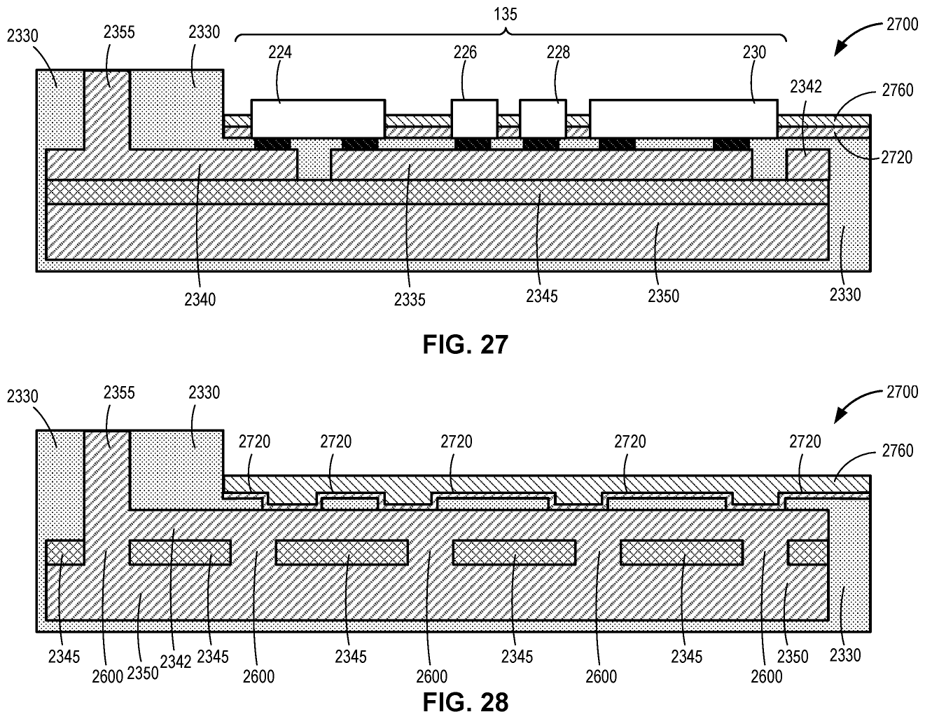

The second example conductive layer 2320 is mechanically coupled to the insulating layer 2315 and the mold layer 2330. The second example conductive layer 2320 is to be electrically coupled to the first conductive layer 2310 by one or more vias 2600 (shown in FIG. 26). In the example of FIG. 23, the second conductive layer 2320 includes the reference plane 2350. In some examples, the second conductive layer 2320 of FIG. 23 is similar in function and/or layout to the second conductive layer 206 of FIGS. 2 and 5.

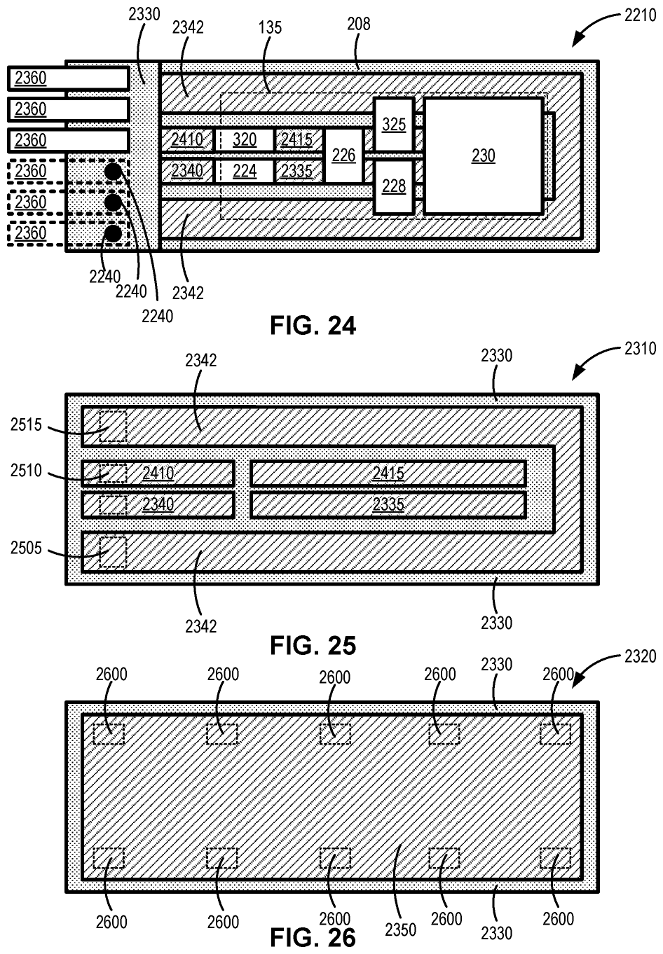

The third example conductive layer 2325 is mechanically coupled to the fifth contacts 2240, the first conductive layer 2310, and the mold layer 2330. The third example conductive layer 2325 is electrically coupled to the fifth contacts 2240 and the first conductive layer 2310. The third example conductive layer 2325 is to offset the fifth contacts 2240 from a surface of the timing package 2210 coupled to the timing circuitry 135. In the example of FIG. 23, the third conductive layer 2325 includes the third trace 2355. In some examples, the third conductive layer 2325 includes additional traces not shown in FIG. 23 but shown in FIG. 24. The example mold layer 2330 encloses the third trace 2355 to define the third conductive layer 2325. In some examples, the height of the third conductive layer 2325 is approximately equal to the difference between the first surface of the timing package 2210 and a second surface of the IC package 2215. The first surface of the timing package 2210 supports the timing circuitry 135. The second surface of the IC package 2215 has the sixth contacts 2250 of FIG. 22. Advantageously, the third example conductive layer 2325 routes signals to and/or from the IC package 2215.

The example protrusion 2235 houses one or more vias that electrically couple an exposed surface of the protrusion 2235 to traces within the timing package 2210. In the example of FIG. 22, the protrusion 2235 reduces EMI exposure of the signals to and/or from the timing package 2210 by routing signals away from the circuitries 2220, 2225, 2230 and the PCB 2205. Advantageously, the example protrusion 2235 provides one surface having the fifth contacts 2240 to be approximately flush with a surface of the IC package 2215 having sixth contacts 2250.

The example mold layer 2330 is mechanically coupled to the layers 2310, 2315, 2320, 2325. In the example of FIG. 23, the mold layer 2330 is coupled to the PCB 2205. In some examples, the mold layer 2330 is mechanically coupled to the PCB 2205 by an adhesive. In other examples, the mold layer 2330 is mechanically coupled to the PCB 2205 by stand-offs. The mold layer 2330 insulates the layers 2310, 2315, 2320, 2325 from irradiated noise from circuitry of the PCB 2205 (e.g., the circuitries 2220, 2225, 2230 of FIG. 22). In some examples, the example mold layer 2330 is configured similar to the mold layer 208 of FIG. 2.

The example traces 2335, 2340, 2355 are electrical interconnects configured to electrically couple one or more components. The example traces 2335, 2340, 2355 are constructed from a conductive material, such as copper, gold, aluminum, etc. In the example of FIG. 23, the traces 2335, 2340, 2355 are configured to route signals to and/or from the fifth contacts 2240 to one or more components of the timing circuitry 135. In some examples, the example traces 2335, 2340, 2355 of FIG. 23 are similar to the traces 210, 212, 220 of FIGS. 2-5, 8-14, 16, and 17.

The example partial reference plane 2342 is electrically coupled to the reference plane 2350. The example partial reference plane 2342 is configured to be coupled to the common potential. In some examples, the example partial reference plane 2342 of FIG. 23 is similar to the partial reference plane 213 of FIG. 2.

The example dielectric 2345 is mechanically coupled to the mold layer 2330, the traces 2335, 2340, 2355, and the reference plane 2350. In some examples, the example dielectric 2345 of FIG. 23 is similar to the dielectric 214 of FIGS. 2, 11-14, 16, and 17.

The example reference plane 2350 is electrically coupled to the partial reference plane 2342. The example reference plane 2350 is configured to be coupled to the common potential. In some examples, the example reference plane 2350 of FIG. 23 is similar to the reference plane 218 of FIG. 2.

The example resistor interconnects 2360 are electrically coupled to the contacts 2240, 2250. The example resistor interconnects 2360 electrically couple the timing package 2210 to the IC package 2215. In some examples, the resistor interconnects 2360 are a plurality of resistors. In such examples, the resistances of the resistor interconnects 2360 may be adjusted based on characteristics of the timing package 2210 and/or the IC package 2215. For example, the resistor interconnects 2360 may be a relatively low resistance (e.g., 0 Ohm resistors) to reduce a resistance between the timing circuitry 135 and the base die 2260. Alternatively, the example resistor interconnects 2360 may be an alternative be referred to as a connector, a wire, etc.

FIG. 24 is a schematic diagram of an example top view of the example timing package 2210 of FIGS. 26 and 27. For purposes of illustration, the portion of the mold layer 208 on the first (e.g., top) surface of the timing package 110 (where the timing circuitry 135 is located) has been removed to reveal the underlying first conductive layer 2310 to which the components of the timing circuitry 135 are connected. A clearer view of the first conductive layer 2310 (unobstructed by the components of the timing circuitry 135) is shown in FIG. 25. In the example of FIG. 24, the timing package 2210 includes the timing circuitry 135, the traces 2335, 2340, the partial reference plane 2342, the resistor interconnects 2360, a fourth example trace 2410, and a fifth example trace 2415.

In this example, there are a total of six resistor interconnects 2360. However, in other examples, a different number may be used. In the illustrated example of FIG. 24, three of the resistor interconnects 2360 are shown in broken lines to reveal the fifth contacts 2240 located on the protrusion 2355. For purposes of simplicity, the IC package 2215 of FIG. 23 has been omitted, which is why the resistor interconnects 2360 appear to extend off the timing package 2210 to the left.

The example traces 2410, 2415 are electrical interconnects configured to electrically couple one or more components. The example traces 2410, 2415 are constructed from a conductive material, such as copper, gold, aluminum, etc. In some examples, the traces 2335, 2340, 2410, 2415 are constructed by placing a conductive material on the dielectric 2345 of FIG. 23. In some examples, the example traces 2410, 2415 are similar to the traces 2335, 2340, 2355 of FIG. 23. In the example of FIG. 24, the traces 2335, 2340, 2410, 2415 are to route signals to and/or from the fifth contacts 2240 of FIGS. 26 and 27 to one or more components of the timing circuitry 135.

FIG. 25 is a schematic diagram of an example top view of the first conductive layer 2310 of FIG. 23 of the timing package 2210 of FIGS. 22-24. In the example of FIG. 25, the first conductive layer 2310 includes the mold layer 2330, the traces 2335, 2340, 2410, 2415, and the partial reference plane 2342. In the example of FIG. 25, the location of the third trace 2355 is represented by a dotted rectangle on the second trace 2340. The location of additional traces (e.g., a sixth example trace 2505, a seventh example trace 2510, and an eighth example trace 2515 of the third conductive layer 2325) are represented by separate dotted rectangles in FIG. 24.

In the example of FIG. 25, the traces 2355, 2505, 2510, 2515 traverse the third conductive layer 2325 to electrically couple the traces 2340, 2410 and the partial reference plane 2342 to the fifth contacts 2240. In this example, the traces 2505, 2515 on the partial reference plane 2342 are large to electrical couple to two adjacent ones of the fifth contacts 2240. In other examples, multiple (e.g., two) smaller traces may be implemented in place of either one of the traces 2505, 2515 represented in FIG. 25. In some instances, the traces 2355, 2505, 2510, 2515 may be referred to and/or implemented as vias.

FIG. 26 is a schematic diagram of an example top view of the second conductive layer 2320 of FIG. 23 of the timing package 2210 of FIGS. 26-29. In the example of FIG. 26, the second conductive layer 2320 includes the mold layer 2330 and the reference plane 2350. In some examples, the reference plane 2350 is electrically coupled to the partial reference plane 2342 through one or more vias 2600 represented in FIG. 26 by dotted rectangles. In some examples, the vias 2600 are similar to the vias 504 of FIG. 5.

FIG. 27 is a block diagram of an example cross-sectional view of an example timing package 2700 taken along line 23-23 of FIG. 22. The timing package 2700 is an example implementation of the timing package 2210 of FIG. 22. In the example of FIG. 27, the timing package 2700 includes the timing circuitry 135, the mold layer 2330, the traces 2335, 2340, the dielectric 2345, the reference plane 2350, an example conductive coating 2720, and an example solder resist layer 2760.

The example conductive coating 2720 is mechanically coupled between the mold layer 2330 and the solder resist layer 2760. The example conductive coating 2720 is adaptive to be coupled to a common potential (e.g., ground or a voltage source supply (Vss)). In some examples, the conductive coating 2720 is coupled to the partial reference plane 2342 of FIGS. 23-25, which supplies the common potential. In some examples, the conductive coating 2720 of FIG. 27 is similar to the conductive coating 1620 of FIGS. 16, 17, and 20. That is, in some examples, the conductive coating 2720 is added and then removed in areas surrounding the contacts for the timing circuitry 135 in a similar manner to what is shown and described above in connection with FIGS. 18-21.

The example solder resist layer 2760 is mechanically coupled to the conductive coating 2720. The example solder resist layer 2760 coats the conductive coating 2720. In some examples, the example solder resist layer 2760 of FIG. 27 is similar to the solder resist layer 1660 of FIGS. 16-19. That is, in some examples, the solder resist layer 2760 is added and then removed in areas surrounding the contacts for the timing circuitry 135 in a similar manner to what is shown and described above in connection with FIGS. 18-21.

FIG. 28 is a block diagram of an example cross-sectional view of the example timing package 2700 of FIG. 27 taken along line 28-28 of FIG. 22. In the example of FIG. 28, the timing package 2700 includes the timing circuitry 135, the mold layer 2330, the reference planes 2342, 2350, the dielectric 2345, the conductive coating 2720, the solder resist layer 2760, and the vias 2600. In the example of FIG. 28, the conductive coating 2720 encloses portions of the mold layer 2330 to be electrically coupled to the partial reference plane 2342, which provides the common potential.

The example vias 2600are mechanically coupled to the reference planes 2342, 2350, the third trace 2355, and the dielectric 2345. The example vias 2600electrically couple the reference planes 2342, 2350. The example vias 2600, allow signals to vertically traverse the dielectric 2345. In some examples, the vias 2600may be referred to as traces. The example vias 2600are constructed from a conductive material, such as copper, gold, aluminum, etc.

The foregoing examples timing packages 110, 1600, 2210 and associated IC packages 112, 2215 teach or suggest different features. Although each example timing package 110, 1600, 2210 and each example IC package 112, 2215 disclosed above has certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features.

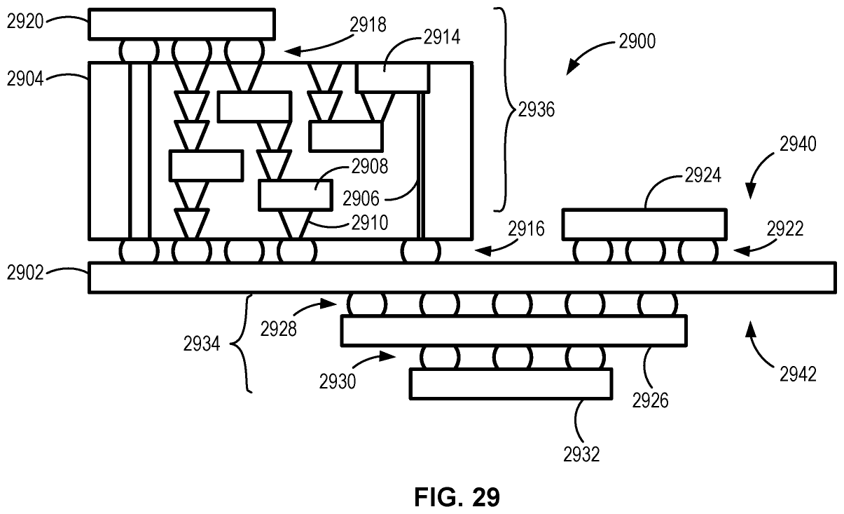

FIG. 29 is a cross-sectional side view of an IC device assembly 2900 that may include one or more of the example timing packages 110, 1600, 2210 disclosed herein. Additionally or alternatively, in some examples, the IC device assembly 2900 of FIG. 29 includes and/or corresponds to any one of the IC packages 112, 2215 that is to be electrically coupled to an example timing package 110, 1600, 2210. The IC device assembly 2900 includes a number of components disposed on a circuit board 2902 (which may be, for example, a motherboard). The IC device assembly 2900 includes components disposed on a first face 2940 of the circuit board 2902 and an opposing second face 2942 of the circuit board 2902; generally, components may be disposed on one or both faces 2940 and 2942. Any of the IC packages discussed below with reference to the IC device assembly 2900 may take the form of the example timing package 110 and/or 2210 of FIGS. 1 and 26.

In some examples, the circuit board 2902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2902. In other examples, the circuit board 2902 may be a non-PCB substrate.

The IC device assembly 2900 illustrated in FIG. 29 includes a package-on-interposer structure 2936 coupled to the first face 2940 of the circuit board 2902 by coupling components 2916. The coupling components 2916 may electrically and mechanically couple the package-on-interposer structure 2936 to the circuit board 2902 and may include solder bumps (as shown in FIG. 29), male and female portions of a socket, an adhesive, an underfill material, and/or any other suitable electrical and/or mechanical coupling structure.

The package-on-interposer structure 2936 may include an IC package 2920 coupled to an interposer 2904 by coupling components 2918. The coupling components 2918 may take any suitable form for the application, such as the forms discussed above with reference to the coupling components 2916. Although a single IC package 2920 is shown in FIG. 29, multiple IC packages may be coupled to the interposer 2904; indeed, additional interposers may be coupled to the interposer 2904. The interposer 2904 may provide an intervening substrate used to bridge the circuit board 2902 and the IC package 2920. The IC package 2920 may be or include, for example, a die (the base die 234 of FIG. 2, the base die 2260 of FIGS. 26 and 27), an IC device (e.g., the CPU 236 of FIG. 2), or any other suitable component. Generally, the interposer 2904 may spread a connection to a wider pitch or reroute a connection to a different connection. For example, the interposer 2904 may couple the IC package 2920 (e.g., a die) to a set of BGA conductive contacts of the coupling components 2916 for coupling to the circuit board 2902. In the example illustrated in FIG. 29, the IC package 2920 and the circuit board 2902 are attached to opposing sides of the interposer 2904; in other examples, the IC package 2920 and the circuit board 2902 may be attached to a same side of the interposer 2904. In some examples, three or more components may be interconnected by way of the interposer 2904.

In some examples, the interposer 2904 may be formed as a PCB, including multiple metal layers separated from one another by layers of dielectric material and interconnected by electrically conductive vias. In some examples, the interposer 2904 may be formed of an epoxy resin, a fiberglass-reinforced epoxy resin, an epoxy resin with inorganic fillers, a ceramic material, or a polymer material such as polyimide. In some examples, the interposer 2904 may be formed of alternate rigid or flexible materials that may include the same materials described above for use in a semiconductor substrate, such as silicon, germanium, and other group III-V and group IV materials. The interposer 2904 may include metal interconnects 2908 and vias 2910, including but not limited to through-silicon vias (TSVs) 2906. The interposer 2904 may further include embedded devices 2914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2904. The package-on-interposer structure 2936 may take the form of any of the package-on-interposer structures known in the art.

The IC device assembly 2900 may include an IC package 2924 coupled to the first face 2940 of the circuit board 2902 by coupling components 2922. The coupling components 2922 may take the form of any of the examples discussed above with reference to the coupling components 2916, and the IC package 2924 may take the form of any of the examples discussed above with reference to the IC package 2920.

The IC device assembly 2900 illustrated in FIG. 29 includes a package-on-package structure 2934 coupled to the second face 2942 of the circuit board 2902 by coupling components 2928. The package-on-package structure 2934 may include a first IC package 2926 and a second IC package 2932 coupled together by coupling components 2930 such that the first IC package 2926 is disposed between the circuit board 2902 and the second IC package 2932. The coupling components 2928, 2930 may take the form of any of the examples of the coupling components 2916 discussed above, and the IC packages 2926, 2932 may take the form of any of the examples of the IC package 2920 discussed above. The package-on-package structure 2934 may be configured in accordance with any of the package-on-package structures known in the art.

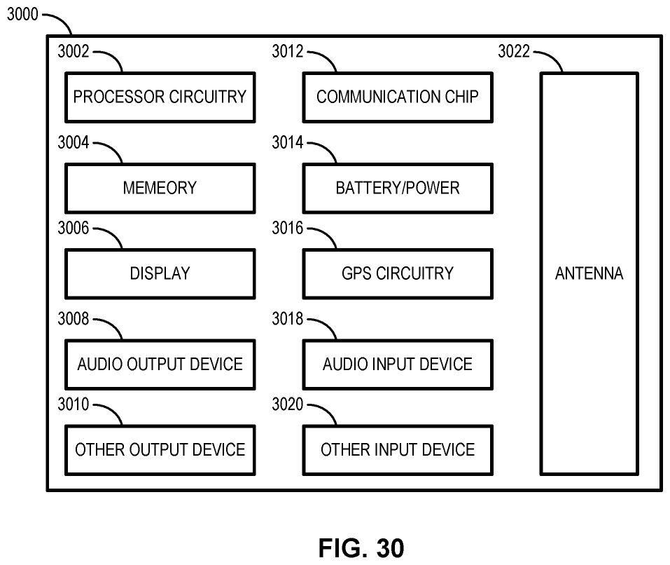

FIG. 30 is a block diagram of an example electrical device 3000 that may include one or more of the example timing packages 110, 1600, 2210 and/or associated IC packages 112, 2215. For example, any suitable ones of the components of the electrical device 3000 may include one or more of the device assemblies 2900, IC devices, or dies disclosed herein, and may be arranged in the example timing packages 110, 1600, 2210 and/or associated IC packages 112, 2215. A number of components are illustrated in FIG. 30 as included in the electrical device 3000, but any one or more of these components may be omitted or duplicated, as suitable for the application. In some examples, some or all of the components included in the electrical device 3000 may be attached to one or more motherboards. In some examples, some or all of these components are fabricated onto a single system-on-a-chip (SoC) die.

Additionally, in various examples, the electrical device 3000 may not include one or more of the components illustrated in FIG. 30, but the electrical device 3000 may include interface circuitry for coupling to the one or more components. For example, the electrical device 3000 may not include a display 3006, but may include display interface circuitry (e.g., a connector and driver circuitry) to which a display 3006 may be coupled. In another set of examples, the electrical device 3000 may not include an audio input device 3018 (e.g., microphone) or an audio output device 3008 (e.g., a speaker, a headset, earbuds, etc.), but may include audio input or output device interface circuitry (e.g., connectors and supporting circuitry) to which an audio input device 3018 or audio output device 3008 may be coupled.

The electrical device 3000 may include programmable circuitry 3002 (e.g., one or more processing devices). The programmable circuitry 3002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 3000 may include a memory 3004, which may itself include one or more memory devices such as volatile memory (e.g., dynamic random-access memory (DRAM)), nonvolatile memory (e.g., read-only memory (ROM)), flash memory, solid state memory, and/or a hard drive. In some examples, the memory 3004 may include memory that shares a die with the programmable circuitry 3002. This memory may be used as cache memory and may include embedded dynamic random-access memory (eDRAM) or spin transfer torque magnetic random access memory (STT-MRAM).

In some examples, the electrical device 3000 may include a communication chip 3012 (e.g., one or more communication chips). For example, the communication chip 3012 may be configured for managing wireless communications for the transfer of data to and from the electrical device 3000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 3012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 3012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 3012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 3012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 3012 may operate in accordance with other wireless protocols in other examples. The electrical device 3000 may include an antenna 3022 to facilitate wireless communications and/or to receive other wireless communications (such as AM or FM radio transmissions).

In some examples, the communication chip 3012 may manage wired communications, such as electrical, optical, or any other suitable communication protocols (e.g., the Ethernet). As noted above, the communication chip 3012 may include multiple communication chips. For instance, a first communication chip 3012 may be dedicated to shorter-range wireless communications such as Wi-Fi or Bluetooth, and a second communication chip 3012 may be dedicated to longer-range wireless communications such as global positioning system (GPS), EDGE, GPRS, CDMA, WiMAX, LTE, EV-DO, or others. In some examples, a first communication chip 3012 may be dedicated to wireless communications, and a second communication chip 3012 may be dedicated to wired communications.

The electrical device 3000 may include battery/power circuitry 3014. The battery/power circuitry 3014 may include one or more energy storage devices (e.g., batteries or capacitors) and/or circuitry for coupling components of the electrical device 3000 to an energy source separate from the electrical device 3000 (e.g., AC line power).

The electrical device 3000 may include a display 3006 (or corresponding interface circuitry, as discussed above). The display 3006 may include any visual indicators, such as a heads-up display, a computer monitor, a projector, a touchscreen display, a liquid crystal display (LCD), a light-emitting diode display, or a flat panel display.

The electrical device 3000 may include an audio output device 3008 (or corresponding interface circuitry, as discussed above). The audio output device 3008 may include any device that generates an audible indicator, such as speakers, headsets, or earbuds.

The electrical device 3000 may include an audio input device 3018 (or corresponding interface circuitry, as discussed above). The audio input device 3018 may include any device that generates a signal representative of a sound, such as microphones, microphone arrays, or digital instruments (e.g., instruments having a musical instrument digital interface (MIDI) output).

The electrical device 3000 may include GPS circuitry 3016. The GPS circuitry 3016 may be in communication with a satellite-based system and may receive a location of the electrical device 3000, as known in the art.

The electrical device 3000 may include any other output device 3010 (or corresponding interface circuitry, as discussed above). Examples of the other output device 3010 may include an audio codec, a video codec, a printer, a wired or wireless transmitter for providing information to other devices, or an additional storage device.

The electrical device 3000 may include any other input device 3020 (or corresponding interface circuitry, as discussed above). Examples of the other input device 3020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 3000 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 3000 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

Further examples and combinations thereof include the following: Example 1 includes an apparatus comprising an integrated circuit package including a package substrate, the package substrate including a first contact and a second contact, the first contact to be electrically coupled to a printed circuit board (PCB), and a timing package distinct from the integrated circuit package, the timing package including a third contact, the third contact to be electrically coupled to the second contact independent of the PCB.

Example 2 includes the apparatus of example 1, wherein the timing package includes a mold layer, the mold layer to be mechanically coupled to a surface of the PCB.

Example 3 includes the apparatus of example 2, wherein the mold layer is to separate conductive components in the timing package from the PCB.

Example 4 includes the apparatus of example 2, wherein the timing package includes conductive coating and a solder resist layer, the conductive coating between the mold layer and the solder resist layer.

Example 5 includes the apparatus of example 1, wherein a portion of the timing package is to be between the PCB and package substrate.

Example 6 includes the apparatus of example 1, wherein the package substrate has a first side and a second side opposite the first side, the first side of the package substrate to face towards the PCB, the timing package has a third side, the third side of the timing package to face away from the PCB, the first contact disposed on the first side of the package substrate, the third contact disposed on the third side of the timing package.

Example 7 includes the apparatus of example 6, wherein the second contact is disposed on the first side of the package substrate.

Example 8 includes the apparatus of example 6, wherein the second contact is disposed on the second side of the package substrate.

Example 9 includes the apparatus of example 6, wherein the timing package further includes a fourth contact, the third side of the timing package has a first surface and a second surface, the first surface offset relative to the second surface, the third contact disposed on the first surface, the fourth contact disposed on the second surface.

Example 10 includes the apparatus of example 9, wherein the first surface is to be farther away from the PCB than the second surface is from the PCB.

Example 11 includes the apparatus of example 9, wherein the first surface is to be closer to the PCB than the second surface is to the PCB.

Example 12 includes the apparatus of example 9, wherein the fourth contact is electrically coupled to the third contact, the apparatus further including a connector to electrically couple the second contact to the third contact.

Example 13 includes the apparatus of example 1, wherein the timing package includes at least one of a resistor-capacitor oscillator or a crystal oscillator, the at least one of the resistor-capacitor oscillator or the crystal oscillator electrically coupled to the package substrate via the second and third contacts.

Example 14 includes an apparatus comprising a mold having a first side and a second side opposite the first side, timing circuitry supported on the first side of the mold, and a contact on the first side of the mold, the contact spaced apart from the timing circuitry, the contact electrically coupled to the timing circuitry via a conductive layer in the mold, the contact to be electrically coupled to an integrated circuit (IC) package independent of a printed circuit board (PCB) to which the IC package is mounted.

Example 15 includes the apparatus of example 14, wherein the conductive layer is a first conductive layer, and the apparatus further includes a second conductive layer disposed in the mold, and a dielectric layer disposed between the first and second conductive layers.

Example 16 includes the apparatus of example 15, wherein the first conductive layer is to be coupled to a common potential, the second conductive layer to route an output of the timing circuitry to the IC package.

Example 17 includes the apparatus of example 14, wherein the second side of the mold is to be mechanically coupled to the PCB, an exterior of the second side of the mold devoid of conductive material.

Example 18 includes the apparatus of example 17, wherein the first side of the mold is to face away from the PCB and to face towards the IC package.

Example 19 includes a method comprising enclosing a conductive layer with an encapsulant, creating first and second contacts on a first side of the encapsulant, the first and second contacts to be electrically coupled to the conductive layer, and coupling timing circuitry to the first contact, the second contact to enable electrical coupling of the timing circuitry to an integrated circuit package external to the encapsulant.

Example 20 includes the method of example 19, wherein the conductive layer is a first conductive material, and the method further includes plating a surface on the first side of the encapsulant with a second conductive layer, and placing a solder resist layer on the second conductive layer.

What is claimed is:

1. An apparatus comprising:
an integrated circuit package including a package substrate, the package substrate including a first contact and a second contact, the first contact to be electrically coupled to a printed circuit board (PCB); and
a timing package distinct from the integrated circuit package, the timing package including a third contact, the third contact to be electrically coupled to the second contact independent of the PCB.

2. The apparatus of claim 1, wherein the timing package includes a mold layer, the mold layer to be mechanically coupled to a surface of the PCB.

3. The apparatus of claim 2, wherein the mold layer is to separate conductive components in the timing package from the PCB.

4. The apparatus of claim 2, wherein the timing package includes conductive coating and a solder resist layer, the conductive coating between the mold layer and the solder resist layer.

5. The apparatus of claim 1, wherein a portion of the timing package is to be between the PCB and package substrate.

6. The apparatus of claim 1, wherein the package substrate has a first side and a second side opposite the first side, the first side of the package substrate to face towards the PCB, the timing package has a third side, the third side of the timing package to face away from the PCB, the first contact disposed on the first side of the package substrate, the third contact disposed on the third side of the timing package.

7. The apparatus of claim 6, wherein the second contact is disposed on the first side of the package substrate.

8. The apparatus of claim 6, wherein the second contact is disposed on the second side of the package substrate.

9. The apparatus of claim 6, wherein the timing package further includes a fourth contact, the third side of the timing package has a first surface and a second surface, the first surface offset relative to the second surface, the third contact disposed on the first surface, the fourth contact disposed on the second surface.

10. The apparatus of claim 9, wherein the first surface is to be farther away from the PCB than the second surface is from the PCB.

11. The apparatus of claim 9, wherein the first surface is to be closer to the PCB than the second surface is to the PCB.

12. The apparatus of claim 9, wherein the fourth contact is electrically coupled to the third contact, the apparatus further including a connector to electrically couple the second contact to the third contact.

13. The apparatus of claim 1, wherein the timing package includes at least one of a resistor-capacitor oscillator or a crystal oscillator, the at least one of the resistor-capacitor oscillator or the crystal oscillator electrically coupled to the package substrate via the second and third contacts.

14. An apparatus comprising:
a mold having a first side and a second side opposite the first side;
timing circuitry supported on the first side of the mold; and
a contact on the first side of the mold, the contact spaced apart from the timing circuitry, the contact electrically coupled to the timing circuitry via a conductive layer in the mold, the contact to be electrically coupled to an integrated circuit (IC) package independent of a printed circuit board (PCB) to which the IC package is mounted.

15. The apparatus of claim 14, wherein the conductive layer is a first conductive layer, and the apparatus further includes:
a second conductive layer disposed in the mold; and
a dielectric layer disposed between the first and second conductive layers.

16. The apparatus of claim 15, wherein the first conductive layer is to be coupled to a common potential, the second conductive layer to route an output of the timing circuitry to the IC package.

17. The apparatus of claim 14, wherein the second side of the mold is to be mechanically coupled to the PCB, an exterior of the second side of the mold devoid of conductive material.

18. The apparatus of claim 17, wherein the first side of the mold is to face away from the PCB and to face towards the IC package.

19. A method comprising:
enclosing a conductive layer with an encapsulant;
creating first and second contacts on a first side of the encapsulant, the first and second contacts to be electrically coupled to the conductive layer; and
coupling timing circuitry to the first contact, the second contact to enable electrical coupling of the timing circuitry to an integrated circuit package external to the encapsulant.

20. The method of claim 19, wherein the conductive layer is a first conductive material, and the method further includes:
plating a surface on the first side of the encapsulant with a second conductive layer; and
placing a solder resist layer on the second conductive layer.
